(19) United States
(12) Patent Application Publication
(10) Pub. No.: US 2022/0137511 A1
(43) Pub. Date: May 5, 2022

(54) RESIST COMPOSITION AND METHOD OF FORMING PATTERN USING THE SAME

(71) Applicant: Inha University Research and Business Foundation, Incheon (KR)

(72) Inventors: Jinkyun LEE, Incheon (KR); Yejin KU, Incheon (KR); Hyuntaek OH, Incheon (KR)

(73) Assignee: Inha University Research and Business Foundation, Incheon (KR)

(21) Appl. No.: 17/515,949

(22) Filed: Nov. 1, 2021

(30) Foreign Application Priority Data
Nov. 2, 2020 (KR) 10-2020-0144301

(51) Int. Cl. G03F 7/038; G03F 7/004; G03F 7/039; G03F 7/20; G03F 7/32

(52) U.S. Cl. CPC G03F 7/0382; G03F 7/0045; G03F 7/325; G03F 7/2004; G03F 7/0392

(57) ABSTRACT

Provided are a resist composition and a method of forming a pattern using the same. According to the inventive concept, the resist composition may include a copolymer represented by Formula 1 below.

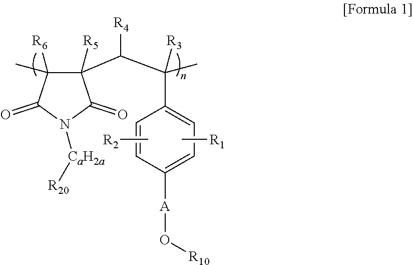

### CROSS-REFERENCE TO RELATED APPLICATIONS

This U.S. non-provisional patent application claims priority under 35 U.S.C. § 119 to Korean Patent Application No. 10-2020-0144301, filed on Nov. 2, 2020, the entire contents of which are hereby incorporated by reference.

### BACKGROUND

The present disclosure herein relates to a resist composition, and more particularly, to a resist composition used for forming a resist pattern.

Photolithography may include an exposure process and a development process. The performance of the exposure process may include exposing a resist film to light with a specific wavelength to induce the change of the chemical structure of the resist film. The performance of the development process may include selectively removing an exposed part or an unexposed part by using a solubility difference between the exposed part and the unexposed part of the resist film.

Recently, according to the increase of integration and miniaturization of semiconductor devices, the constituent elements of the semiconductor device are required to have minute pitches and widths. There is an increasing importance issue on a resist compound for forming minute patterns.

### SUMMARY

The task for solving of the present disclosure is to provide a resist composition having high sensitivity to light and improved patterning properties.

The task for solving of the present disclosure is not limited to the aforementioned tasks, and unreferred other tasks may be clearly understood by a person skilled in the art from the description below.

The inventive concept relates to a resist composition and a method of forming a pattern using the same. According to the inventive concept, the composition may include a copolymer represented by Formula 1.

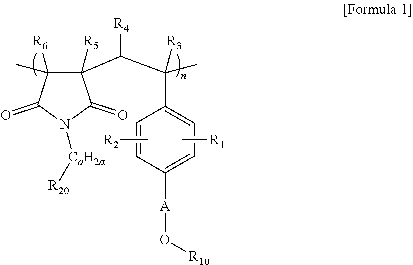

In Formula 1, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, R₁₀ is an alkyl group of 1 to 16 carbon atoms, R₂₀ is perhalogenated alkyl of 2 to 16 carbon atoms, perhalogenated alkyl ether perhalogenated alkyl of 2 to 16 carbon atoms, or halogenated-arene of 2 to 16 carbon atoms, “a” is any one integer selected from 1 to 11, and “n” is any one integer selected from 10 to 150.

In an embodiment, the composition may further include a photo acid generator.

In an embodiment, in Formula 1, R₂₀ may be perfluoroalkyl of 2 to 11 carbon atoms or perfluoroalkyl ether perfluoroalkyl of 2 to 11 carbon atoms.

In an embodiment, a material represented by Formula 1 may include a material represented by Formula 2.

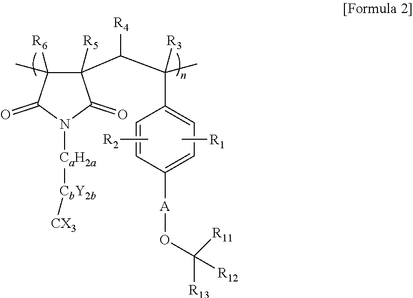

In Formula 2, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, each X is independently any one selected among F, Cl, Br and I, “a” is any one integer selected from 1 to 11, “b” is any one integer selected from 1 to 15, R₁₁, R₁₂ and R₁₃ are each independently an alkyl group of 1 to 5 carbon atoms, and “n” is any one integer selected from 10 to 150.

In an embodiment, in Formula 2, X and Y may be F.

In an embodiment, A in Formula 1 may be represented by Formula A.

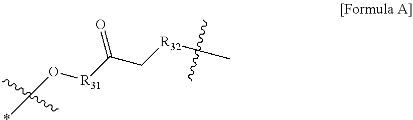

In Formula A, R₃₁ and R₃₂ are each independently any one selected from a single bond or a divalent alkyl group of 1 to 3 carbon atoms, and * is a part bonded to a benzene ring.

In an embodiment, the copolymer may have a glass transition temperature of about 110° C. to about 150° C., and the copolymer may have a polydispersity index of about 1 to about 1.5.

In an embodiment, a material represented by Formula 1 may include a material represented by Formula 3A.

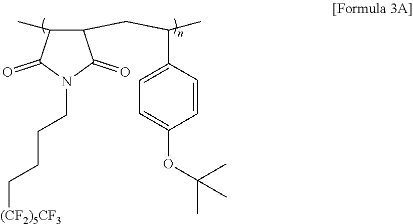

In Formula 3A, “n” is an integer between 10 and 150.

In an embodiment, a material represented by Formula 1 may include a material represented by Formula 3B.

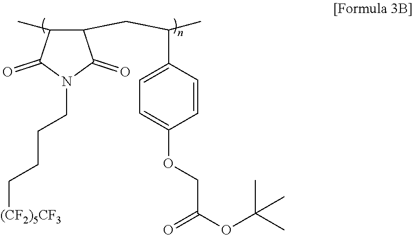

In Formula 3B, “n” is any one integer selected from 10 to 150.

In an embodiment, a material represented by Formula 1 may include a material represented by Formula 3C.

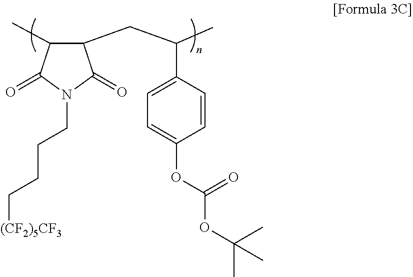

In Formula 3C, “n” may be any one integer selected from 10 to 150.

According to the inventive concept, the method of forming a pattern may include applying a compound represented by Formula 1 below on a substrate to form a resist film; and patterning the resist film.

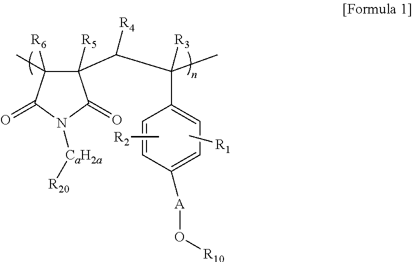

In Formula 1, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, R₁₀ is an alkyl group of 1 to 16 carbon atoms, R₂₀ is perhalogenated alkyl of 2 to 16 carbon atoms, perhalogenated alkyl ether perhalogenated alkyl of 2 to 16 carbon atoms, or halogenated-arene of 2 to 16 carbon atoms, “a” is any one integer selected from 1 to 11, and “n” is any one integer selected from 10 to 150.

In an embodiment, the patterning of the resist film may include exposing the resist film to light to form an exposed part and an unexposed part; and performing a development process using a developing solution on the resist film.

In an embodiment, the developing solution may include a polar developing solution, and the performing of the development process may include removing the exposed part of the resist film.

In an embodiment, the developing solution may include a nonpolar developing solution, and the performing of the development process may include removing the unexposed part of the resist film.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a plan view showing a resist pattern according to embodiments;

FIG. 2 to FIG. 5 are diagrams for explaining a method of forming a lower pattern according to embodiments;

FIG. 6 and FIG. 7 are diagrams for explaining a method of forming a lower pattern according to another embodiments;

FIG. 8A shows nuclear magnetic resonance spectrum results of a product of Experimental Example 1A;

FIG. 8B shows nuclear magnetic resonance spectrum results of a product of Experimental Example 1B;

FIG. 8C shows nuclear magnetic resonance spectrum results of a product of Experimental Example 1C;

FIG. 9 is a graph for evaluating solubility properties of resist films of Experimental Example 5A and Experimental Example 5B;

FIG. 10 is a graph for evaluating solubility properties of resist thin films of Experimental Example 6A and Experimental Example 6B, in cases of including an ionic photo acid generator;

FIG. 11A is graphs for evaluating solubility properties of resist thin films of Experimental Example 7A and Experimental Example 7B with respect to a developing agent of PF-7600 and nBA;

FIG. 11B is graphs for evaluating solubility properties of resist thin films of Experimental Example 7C and Experimental Example 7D with respect to a developing agent of PF-7600 and nBA;

FIG. 11C is graphs for evaluating solubility properties of resist thin films of Experimental Example 7E and Experimental Example 7F with respect to a developing agent of PF-7600 and nBA;

FIG. 12 is a graph for evaluating solubility properties of resist films of Experimental Example 5A, Experimental Example 5B, Comparative Example 2A and Comparative Example 2B;

FIG. 13 is a graph for evaluating solubility properties of resist films of Experimental Example 8A, Experimental Example 8B and Experimental Example 8C;

FIG. 14 is a graph for evaluating solubility properties of resist thin films of Experimental Example 9A, Experimental Example 9B, and Experimental Example 9C, in cases of including an ionic photo acid generator;

FIG. 15 is a graph for evaluating solubility properties of resist patterns after performing an exposure process to extreme ultraviolet of Experimental Example 12A and Experimental Example 12B; and

FIG. 16 is a graph for evaluating solubility properties of resist patterns on extreme ultraviolet of Experimental Example 13A and Experimental Example 13B, in cases of including an ionic photo acid generator;

### DETAILED DESCRIPTION

Preferred embodiments of the inventive concept will be explained with reference to the accompany drawings for sufficient understanding of the configurations and effects of the inventive concept. The inventive concept may, however, be embodied in various forms, have various modifications and should not be construed as limited to the embodiments set forth herein. The embodiments are provided to complete the disclosure of the inventive concept through the explanation of the embodiments and to completely inform a person having ordinary knowledge in this technical field to which the inventive concept belongs of the scope of the inventive concept. A person having ordinary knowledge in this technical field might understand suitable environments in which the inventive concept may be performed.

The terms used herein are to explain the embodiments but are not to limit the inventive concept. In the disclosure, the singular forms are intended to include the plural forms as well, unless the context clearly indicates otherwise. The terms “comprises” and/or “comprising,” used in the disclosure, specify the presence of stated materials, elements, steps and/or devices, but do not preclude the presence or addition of one or more other materials, elements, steps and/or devices.

In the disclosure, an alkyl group may be a linear alkyl group, a branched alkyl group, or a cyclic alkyl group. The carbon number of the alkyl group is not specifically limited, but the alkyl group may be an alkyl group of 1 to 3 carbon atoms. Examples of the alkyl group may include a methyl group, an ethyl group and a propyl group, without limitation.

In the disclosure, examples of halogen may include fluorine (F), chlorine (Cl), bromine (Br) and iodine (I), without limitation.

In the disclosure, the term “substituted or unsubstituted” corresponds to substituted or unsubstituted with one or more substituents selected from the group consisting of a hydrogen atom, a deuterium, a halogen atom, an ether group, a halogenated alkyl group, a halogenated alkoxy group, a halogenated ether group, an alkyl group and a hydrocarbon ring group. In addition, each of the example substituents may be substituted or unsubstituted. For example, an alkyl ether group may be interpreted as an ether group.

In the disclosure, a perhalogenated alkyl group may include perhalogenated alkyl ether perhalogenated alkyl group, and a perfluoroalkyl group may include perfluoroalkyl ether perfluoroalkyl group.

In the disclosure, an alkyl group may include a monovalent alkyl group, a divalent alkyl group, a trivalent alkyl group and a tetravalent alkyl group.

In the chemical formulae in the disclosure, in the case where a chemical bond is not drawn where a chemical bond is required, it may mean that a hydrogen atom is bonded at that position, unless otherwise defined.

In the disclosure, same reference symbol may refer to the same constituent element throughout the text.

Hereinafter, a composition according to the inventive concept will be explained.

According to the inventive concept, the composition may be a resist composition. The resist composition may be used for forming a pattern or for manufacturing a semiconductor device. For example, the resist composition may be used in a patterning process for manufacturing a semiconductor device. The resist composition may be an extreme ultraviolet (EUV) resist composition, a long wavelength ultraviolet resist composition, or an electron beam resist composition. The extreme ultraviolet may mean ultraviolet having a wavelength of about 10 nm to about 124 nm, particularly, about 13.0 nm to about 13.9 nm, more particularly, about 13.4 nm to about 13.6 nm. The long wavelength ultraviolet may mean ultraviolet having a wavelength of about 360 nm to about 370 nm. According to embodiments, the composition may include a copolymer. Particularly, the copolymer may be an alternating copolymer. The copolymer may show excellent mechanical strength. The copolymer may be represented by Formula 1 below.

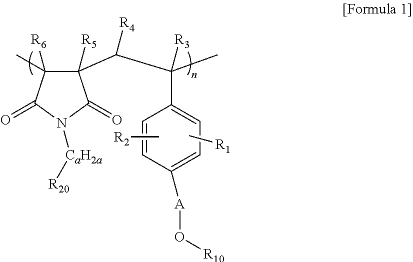

In Formula 1, R₁, R₂, R₃, R₄, R₅ and R₆ may be each independently any one selected among hydrogen, deuterium and alkyl of 1 to 3 carbon atoms, A may be a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, R₁₀ may be an alkyl group of 1 to 16 carbon atoms, R₂₀ may be perhalogenated alkyl of 2 to 16 carbon atoms, perhalogenated alkyl ether perhalogenated alkyl of 2 to 16 carbon atoms, or halogenated-arene of 2 to 16 carbon atoms, “a” may be any one integer selected from 1 to 11, and “n” may be any one integer selected from 10 to 150.

According to an embodiment, in Formula 1, R₁₀ may be tertiary alkyl of 1 to 15 carbon atoms.

R₂₀ of Formula 1 may be a fluoroalkyl group of 2 to 11 carbon atoms. For example, R₂₀ may be perfluoroalkyl of 2 to 11 carbon atoms or perfluoroalkyl ether perfluoroalkyl of 2 to 11 carbon atoms.

According to an embodiment, in Formula 1, R₂₀ may be —(C_{b}Y_{2b})—CX₃, X and Y may be each independently any one selected from H, F, Cl, Br, or I, and “b” may be an integer between 1 and 15.

In another embodiment, in Formula 1, R₂₀ may be fluorine-substituted fluoroarene.

According to embodiments, a material represented by Formula 1 may include a material represented by Formula 2.

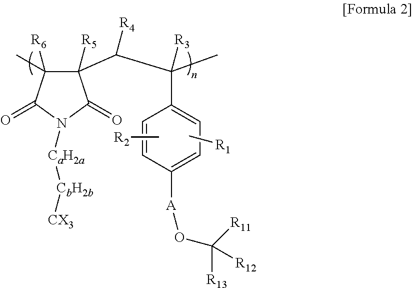

In Formula 2, each X is independently any one selected from F, Cl, Br or I, “b” is any one integer selected from 1 to 15, R₁₁, R₁₂ and R₁₃ are each independently an alkyl group of 1 to 5 carbon atoms, and “a”, A, Ru, R₂, R₃, R₄, R₅, R₆ and “n” are the same as defined in Formula 1.

According to an embodiment, X and Y in Formula 2 may be each independently F or I. For example, X and Y may be F.

In an embodiment, in Formula 1 and Formula 2, A may be a divalent alkyl group of 1 to 5.

According to another embodiment, in Formula 1 and Formula 2, A may be a group represented by Formula A.

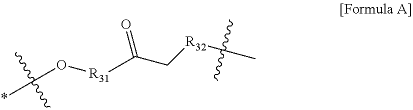

In Formula A, R₃₁ and R₃₂ may be each independently any one selected from a single bond or a divalent alkyl group of 1 to 3 carbon atoms, and * may be a part bonded to a benzene ring.

The group represented by Formula A may include the groups represented by Formula A1 and Formula A2 below.

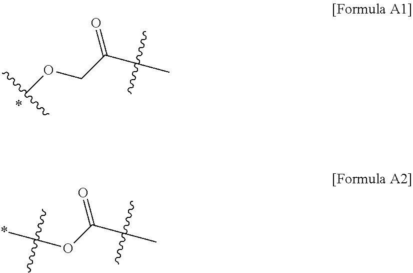

In Formula A1 and Formula A2, * may be a part bonded to a benzene ring.

According to embodiments, a material represented by Formula 2 may include at least one selected from materials represented by Formula 3A, Formula 3B and Formula 3C below.

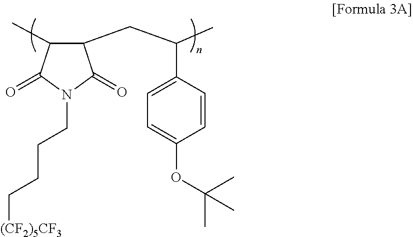

In Formula 3A, “n” may be an integer selected from 10 and 150.

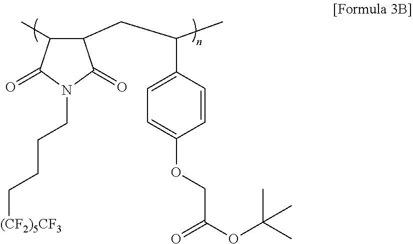

In Formula 3B, “n” may be any one integer selected from 10 to 150.

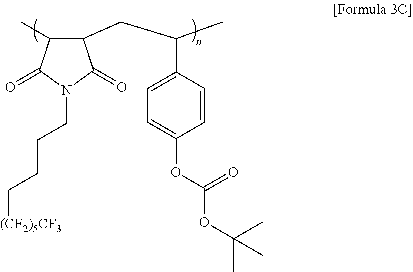

In Formula 3C, “n” may be any one integer selected from 10 to 150.

According to another embodiment, R₂₀ in Formula 1 may be any one selected from the groups represented by Formula 4-1 to Formula 4-3 below.

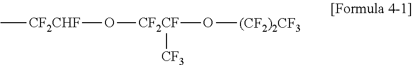

—CF₂CHFO(CF₂)₃OCF₃ [Formula 4-2]

—CF₂CHFO(CF₂)₂CF₃ [Formula 4-3]

In the explanation below, a perhalogenated alkyl group may be defined to include a perhalogenated alkyl ether perhalogenated alkyl group, and the perhalogenated alkyl group may be defined to include a perfluoroalkyl ether perfluoroalkyl group.

The resist composition according to embodiments may further include a photo acid generator (PAG). The photo acid generator may include, for example, the materials represented by Formula 5 and Formula 6 below. The material represented by Formula 5 may be a nonionic photo acid generator. The material represented by Formula 6 may be an ionic photo acid generator.

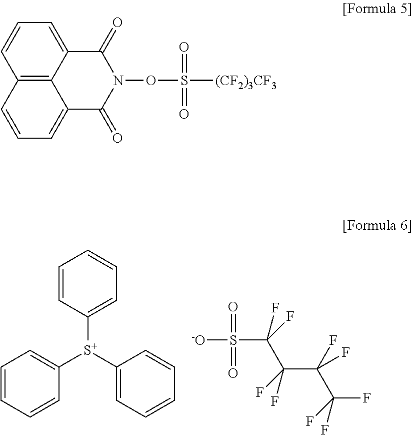

According to embodiments, the composition may include a copolymer, and the copolymer may include a first polymerization unit and a second polymerization unit. The first polymerization unit may be induced from a maleimide monomer which is substituted with a halogenated alkyl group. The halogenated alkyl group may be represented by R₂₀ in Formula 1. A resist film includes a compound represented by Formula 1 and may show improved sensitivity and light absorbance during an exposure process. Accordingly, the efficiency of the manufacturing process of a semiconductor device may be improved. In this case, the sensitivity means sensitivity to ultraviolet or electron beam, and the light absorbance may be absorbance of ultraviolet or electron beam. The ultraviolet may include extreme ultraviolet or long wavelength ultraviolet. By the irradiation of the light, intermolecular bonding reaction between halogenated alkyl groups may be generated. The intermolecular bonding reaction may be crosslinking reaction. As a result of the intermolecular bonding reaction, an exposed part of a resist film may have a chemical structure different from an unexposed part.

In an embodiment, in a development process of a resist film, a developing solution may include a high fluorine-based solution. In Formula 1, R₂₀ may include a halogenated alkyl group (for example, perhalogenated alkyl group). The resist film may include a plurality of the same elements (halogen elements) as the developing solution, and may be easily dissolved in the developing solution. The halogen may be fluorine.

The second polymerization unit may be different from the first polymerization unit. The second polymerization unit may be induced from a styrene monomer in which an acid-cleavable protective group is substituted. The acid-cleavable protective group may include an alkyl group bonded to an oxygen atom. For example, the acid-cleavable protective group may be represented by —OR₁₀ in Formula 1.

In a post-exposure bake (PEB) process, the decomposition reaction of the acid-cleavable protective group of a copolymer may be generated. For example, the bond between oxygen (O) and R₁₀ of —OR₁₀ may be cleaved. If R₁₀ includes a tertiary alkyl group, a product may be stabilized even further, and the decomposition reaction may be accelerated. The photo acid generator may produce an acid by light. The acid may mean hydrogen cations. The acid may act as a catalyst, and by the acid catalyst, the decomposition reaction of the acid-cleavable protective group may be accelerated. Accordingly, the resist film may show improved sensitivity. The decomposition reaction of the acid-cleavable protective group in an exposure process may be performed by, for example, Reaction 1A, Reaction 1B, or Reaction 1C.

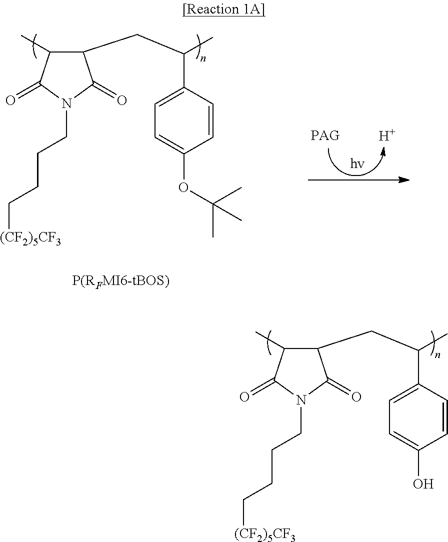

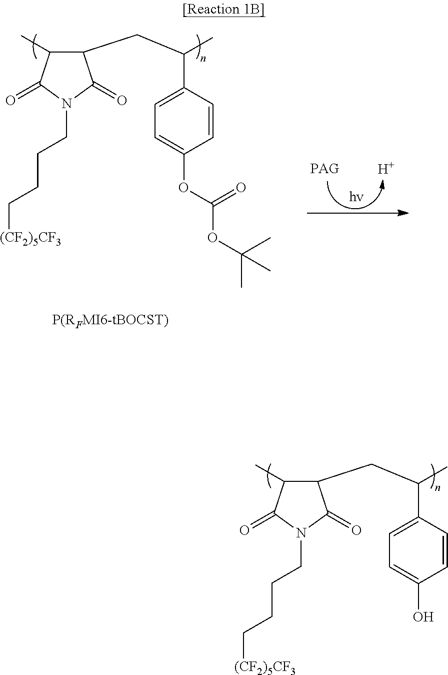

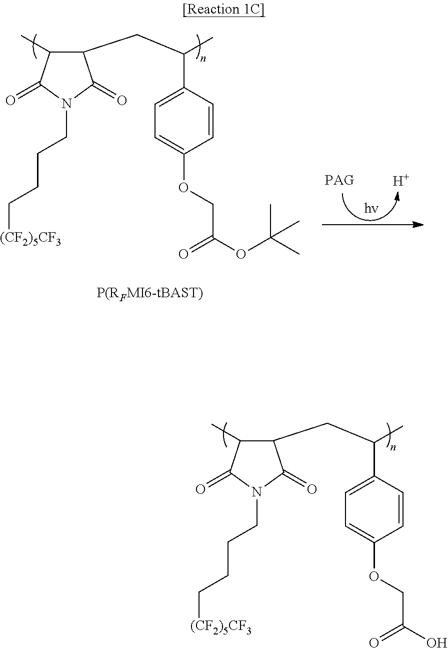

According to embodiments, after the decomposition reaction, the second polymerization unit of the copolymer (for example, a polymerization unit including styrene) may have a —OH group. Accordingly, the second polymerization unit of the copolymer may show polarity. The exposed part of the resist film may have high solubility in a polar developing solution. The exposed part of the resist film may have reduced solubility in a nonpolar developing solution. Accordingly, the precision of patterning in a development process may be improved.

If the chemical composition or chemical structure of a resist material is nonuniform, the resolution properties of a resist pattern and the line-edge roughness (LER) properties may be deteriorated. According to the inventive concept, the copolymer is an alternating copolymer and may have uniform chemical composition and uniform chemical structure. Particularly, since the first polymerization unit and the second polymerization unit are alternately arranged, halogenation functional groups and acid-cleavable protective groups may be distributed uniformly in a compound. If multiple copolymers represented by Formula 1 are provided, the total number ratio of the halogenation functional groups and the total number ratio of the acid-cleavable protective groups of the multiple copolymers may be substantially the same. A resist film including the copolymer may show high resolution during an exposure process. In a development process, any one among the exposed part and the unexposed part of the resist film may be dissolved uniformly with respect to a developing solution. Accordingly, a resist pattern may be formed with minute widths and pitches.

Since the copolymer is an alternating copolymer, the copolymer may have narrow molecular weight distribution according to polymerization conditions. The molecular weight distribution may be evaluated by a polydispersity index. The polydispersity index (hereinafter, PDI) of the copolymer may commonly have a value of about 2. According to the inventive concept, a polymer having a polydispersity index of “about 1.5 or less” may be prepared through controlling the conditions of polymerization reaction. For example, the polydispersity index of the copolymer may be about 1 to about 1.5. For example, if the copolymer satisfies the reduced polydispersity index conditions, the copolymer may show improved uniformity of a chemical composition and improved uniformity of a chemical structure. Accordingly, if a resist pattern is formed using the copolymer, the resolution of the resist pattern may be improved even further. The resist pattern may have improved line-edge roughness (LER) properties and/or improved line width roughness (LWR) properties.

The composition includes a copolymer and a halogenated alkyl group (for example, a perhalogenated alkyl group), and may have a relatively high glass transition temperature. For example, the compound may have a glass transition temperature of about 110° C. to about 150° C. Accordingly, a pattern formed using the composition may have high durability and stability.

According to embodiments, a resist composition may not include a metal element. Accordingly, contamination problems due to a metal element may not be generated. The contamination may include contamination of equipments or contamination of the constituent elements of a semiconductor device.

The resist composition according to embodiments may have the merits of a non-chemically amplified photoresist (nCAR). For example, the resist composition may show excellent resolution. The resist composition may show the merits of a chemically amplified photoresist (CAR). For example, the resist composition may show excellent sensitivity.

Hereinafter, a method of preparing a compound according to embodiments will be explained.

The preparation of a compound according to embodiments may include synthesizing a first monomer, synthesizing a second monomer, and performing polymerization reaction of the first monomer and the second monomer.

The first monomer may include maleimide to which a halogenated alkyl group is bonded. The synthesis of the first monomer may include substituting hydrogen bonded to the nitrogen of the maleimide with a high fluoroalkyl chain by applying Mitsunobu reaction conditions. For example, the synthesis of the first monomer may be performed by Reaction 2 below.

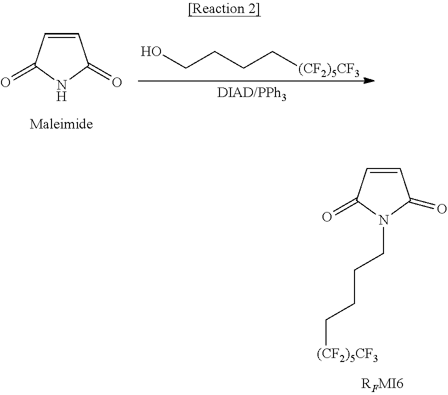

(In Reaction 2, DIAD is diisopropyl azocarboxylate, and PPh₃ is triphenylphosphine.)

The second monomer may include styrene to which an acid-cleavable protective group is bonded or styrene derivatives to which an acid-cleavable protective group is bonded. For example, 4-tert-butoxystyrene (hereinafter, tBOS) may be used as the second monomer. The synthesis of the second monomer may be performed by Reaction 3. For example, hydroxybenzaldehyde is used as a starting material, and Wittig reaction may be performed with respect to the starting material. The carbonyl group of hydroxybenzaldehyde is transformed into alkene, and tert-butyl acetate and tert-butoxycarbonyl are introduced to a hydroxyl functional group to prepare 4-(tert-butyl acetate)styrene (hereinafter, tBAST) and 4-[(tert-butoxycarbonyl)oxy]styrene (hereinafter, tBOCST), respectively.

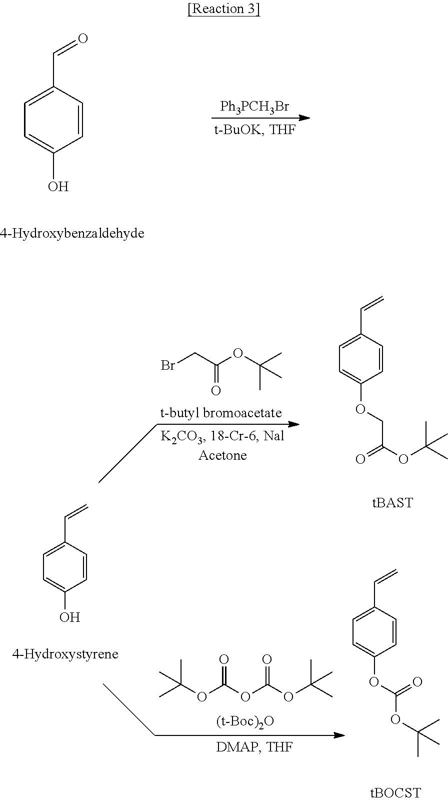

(In Reaction 3, THF is tetrahydrofuran, and DMAP is dimethylaminopyridine.)

The polymerization reaction of the first monomer and the second monomer may be performed by reversible addition fragmentation chain transfer (RAFT) polymerization reaction. The styrene and/or styrene derivatives of the second monomer may have double bonds with high electron density, and the first monomer may have double bonds with deficient electrons. Accordingly, through the RAFT polymerization reaction of the first monomer and the second monomer, an alternating copolymer may be synthesized. In the polymerization reaction, 4-cyano-4-dodecyl sulfanylthiocarbonyl)sulfanyl pentanoi c acid (hereinafter, CDSTSP) may be used as a RAFT agent, and 2,2′-azobis(2-methylpropionitrile) (hereinafter, AIBN) may be used as a polymerization initiator.

For example, the polymerization reaction of the first monomer and the second monomer may be performed according to Reaction 4A, Reaction 4B, or Reaction 4C below. The product of Reaction 4A may be a material represented by Formula 3A. The product of Reaction 4B may be a material represented by Formula 3B. The product of Reaction 4C may be a material represented by Formula 3C.

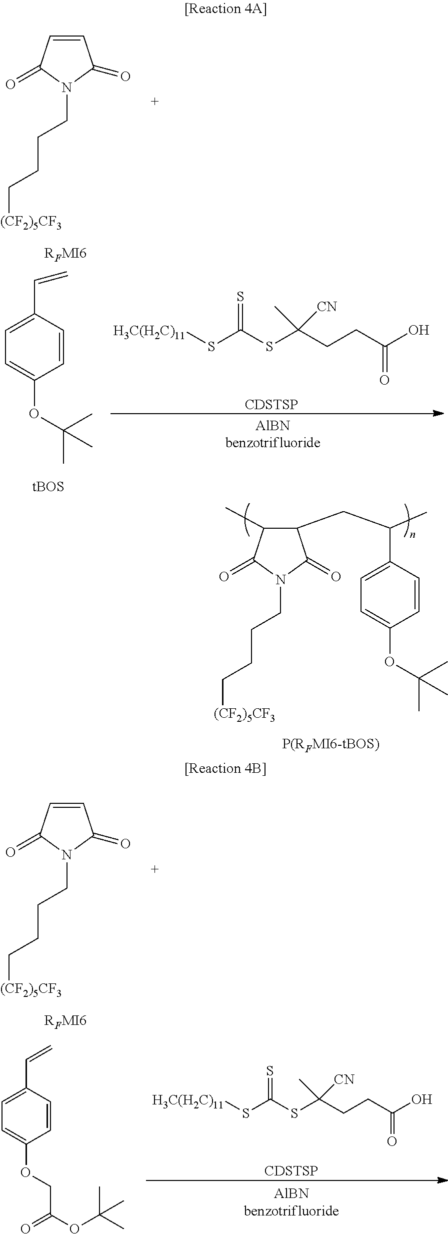

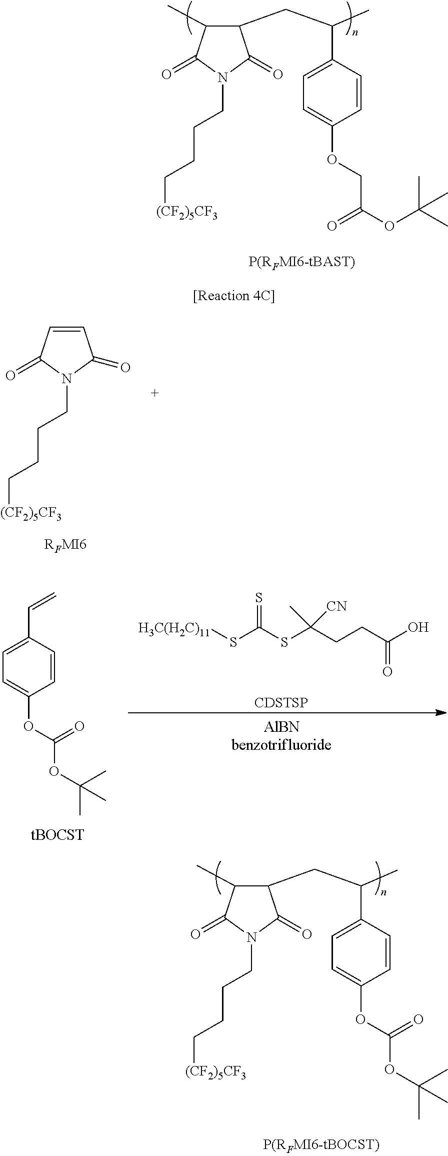

Hereinafter, a method of forming a pattern using the composition according to embodiments and a method of manufacturing a semiconductor device will be explained.

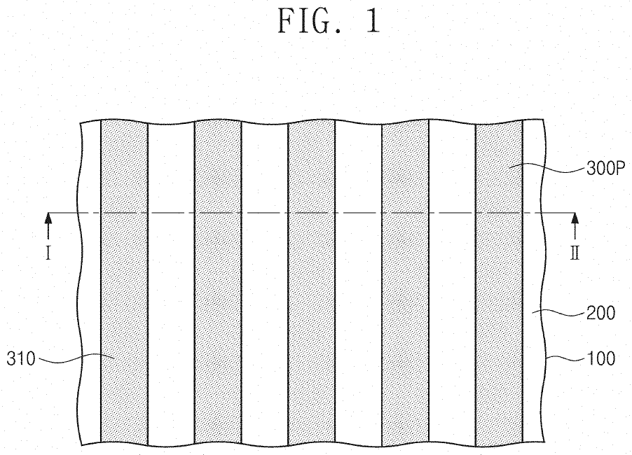

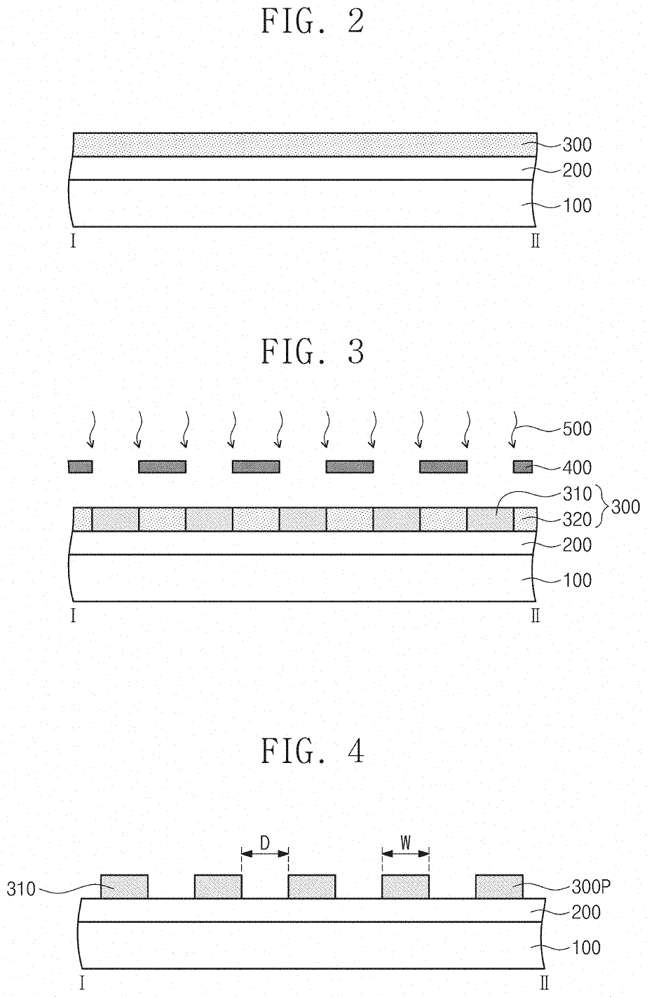

FIG. 1 is a plan view showing a resist pattern according to embodiments. FIG. 2 to FIG. 5 are diagrams for explaining the formation of a lower pattern according to embodiments, and correspond to cross-sections cut along line I-II in FIG. 1.

Referring to FIG. 1 and FIG. 2, a substrate 100 may be prepared. A lower film 200 and a resist film 300 may be formed on the substrate 100 one by one. The lower film 200 may be an etching target film. The lower film 200 may be formed using any one selected from a semiconductor material, a conductive material, or an insulating material, or combinations thereof. In addition, the lower film 200 may be formed as a single film or may include multiple staked films. Though not shown, films may be additionally provided between the substrate 100 and the lower film 200.

A resist composition may be prepared. The resist composition may include the above-explained copolymer and a photo acid generator. The resist composition may be applied on the lower film 200 to form the resist film 300. The application of the resist composition may be performed by spin coating. On the applied resist composition, a heat treatment process may be additionally performed. The heat treatment process may be performed at about 80° C. to about 200° C. The heat treatment process may correspond to a bake process of the resist film 300.

Referring to FIG. 1 and FIG. 3, an exposure process of the resist film 300 may be performed. For example, the resist film 300 may be exposed to light 500. The light 500 may be electron beam, extreme ultraviolet, or long wavelength ultraviolet. Before irradiating the light 500, a photo mask 400 may be positioned on the resist film 300. A first part 310 of the resist film 300 exposed by the photo mask 400 may be exposed to the light 500. The first part 310 of the resist film 300 may be an exposed part. If the resist film 300 is exposed to the light 500, the chemical bonds of the halogenated alkyl groups of a copolymer may be cleaved, and radicals may be produced. The radicals may be free radicals. For example, the halogenated alkyl group may be represented by R₂₀ in the above-explained Formula 1. In Formula 1, R₂₀ may include perhalogenated alkyl of 2 to 16 carbon atoms or perhalogenated alkyl ether perhalogenated alkyl of 2 to 16 carbon atoms. More particularly, R₂₀ may include perfluoroalkyl or perfluoroalkyl ether perfluoroalkyl. In this case, the resist film 300 may have high light absorbance with respect to electron beam and extreme ultraviolet. If the halogen content or oxygen content increases in a compound, radicals may be formed more by the irradiation of the light 500. Due to the radicals, intermolecular bonding reaction between multiple halogenated alkyl groups of the copolymer (for example, perhalogenated alkyl groups) may be generated. The intermolecular bond may be a crosslinked bond. Accordingly, the chemical structure of the copolymer of the first part 310 of the resist film 300 exposed to the light 500 may be changed. For example, the first part 310 of the resist film 300 may have a crosslinked network structure, and the crosslinked network structure may be formed by the crosslinking bond of the halogenated alkyl groups.

The second part 320 of the resist film 300 may not be exposed to the light 500. The second part 320 of the resist film 300 may be an unexposed part. The chemical structure of the copolymer in the second part 320 of the resist film 300 may not be changed. Accordingly, after completing the irradiation of the light 500, the first part 310 and the second part 320 of the resist film 300 may have different chemical structures.

According to embodiments, a post-exposure bake (PEB) process may be further performed on the resist film 300. In the post-exposure bake process, the decomposition reaction of an acid-cleavable protective group may arise. For example, a bond between oxygen (O) and R₁₀ of —OR₁₀ may be cleaved, and a —OH group may be formed. The decomposition reaction of the acid-cleavable protective group may be performed according to the above-explained Reaction 1A, Reaction 1B, or Reaction 1C. In the post-exposure bake process, a photo acid generator may produce an acid, and the acid may act as a catalyst. By the acid, the decomposition reaction of the acid-cleavable protective group may be promoted. After an exposure process, the second polymerization unit of the copolymer in the first part 310 of the resist film 300 (for example, a polymerization unit including styrene) may have an OH group. Due to the OH group, the polarity of the first part 310 of the resist film 300 may increase.

The crosslinked network structure of the copolymer may prevent the diffusion of an acid from the first part 310 to the second part 320 of the resist film 300. Accordingly, an OH group may not be formed in the second part 320 of the resist film 300. The first part 310 of the resist film 300 may have different properties from the second part 320. For example, the first part of the resist film 300 may be polar, and the second part 320 may be nonpolar.

After the exposure process, the photo mask 400 may be removed.

Referring to FIG. 1 and FIG. 4, the second part 320 of the resist film 300 may be removed by a developing solution to form a resist pattern 300P. The resist pattern 300P may be formed by a patterning process including the exposure process and development process of the resist film 300. The resist pattern 300P may correspond to the first part 310 of the resist film 300. The developing solution may be a nonpolar developing solution. The nonpolar developing solution may include a high fluorine-based solvent and a solution including thereof. The high fluorine-based solution may mean a solution having a high fluorine content. For example, the nonpolar developing solution may include at least one among hydrofluoro ether (HFE) and perfluorocarbon (PFC). The first part 310 of the resist film 300 includes an OH group and may have a low solubility in the nonpolar developing solution. The second part 320 is nonpolar and may have high solubility in the nonpolar developing solution. Accordingly, the second part 320 of the resist film 300 may be selectively removed. The resist pattern 300P may be a negative tone pattern.

If the chemical composition or chemical structure of a resist material is nonuniform, the resist material may be dissolved in the developing solution relatively nonuniformly. According to embodiments, the copolymer is an alternating copolymer, and multiple copolymers may have substantially the same composition ratio. Accordingly, in a development process, the selectivity of the second part 320 against the first part 310 of the resist film 300 may increase. The second part 320 of the resist film 300 may be uniformly dissolved in the developing solution. Accordingly, the resist pattern 300P formed from the resist composition may have a narrow width W. For example, the width W of the resist pattern 300P may be about 20 nm to about 300 nm. The resist pattern 300P formed from the composition may include multiple pattern parts, and a distance D between the pattern parts may be relatively narrow. For example, the distance D between the pattern parts of the resist pattern 300P may be about 20 nm to about 300 nm.

According to embodiments, the high fluorine-based solution is used as the developing solution, and the developing solution may have low surface tension. Accordingly, the pattern collapse of the resist pattern 300P during the development process may be prevented. The pattern collapse may mean the collapse of a part of the resist film 300 developed (for example, the second part 320) during drying due to the surface tension of a solvent. The development process of the resist pattern 300P may be performed chemically stably. Accordingly, the resist pattern 300P may be formed with a minute width W and distance D.

As in FIG. 1, the resist pattern 300P may have a linear and planar shape. For example, the resist pattern 300P may include extended parts in one direction. However, the planar shape of the resist pattern 300P may be changed into various shapes including a zigzag shape, a honeycomb shape, and a circular shape. The resist pattern 300P may expose a lower film 200.

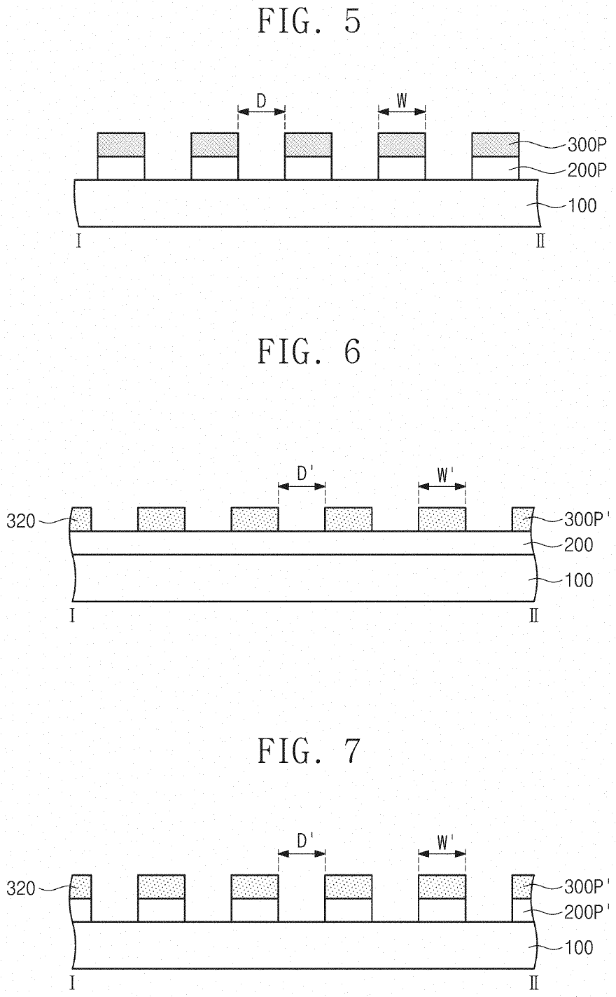

Referring to FIG. 1 and FIG. 5, the lower film 200 exposed by the resist pattern 300P may be removed to form a lower pattern 200P. The removal of the lower film 200 may be performed by an etching process. The lower film 200 may have an etching selectivity with respect to the resist pattern 300P. The lower pattern 200P may expose the substrate 100. In another embodiment, the lower pattern 200P may expose another film disposed between the substrate 100 and the lower pattern 200P. After that, the resist pattern 300P may be removed. Accordingly, the pattern shape may be completed. The pattern may mean the lower pattern 200P. The width of the lower pattern 200P may correspond to the width W of the resist pattern 300P. Since the resist pattern 300P has a narrow width W, the lower pattern 200P may be formed into a narrow width. The distance between the pattern parts of the lower pattern 200P may correspond to the distance D between the pattern parts of the resist pattern 300P.

According to embodiments, the lower pattern 200P may be the constituent element of a semiconductor device. For example, the lower pattern 200P may be a semiconductor patter, conductive pattern, or insulating pattern in the semiconductor device.

FIG. 6 and FIG. 7 are diagrams for explaining a method of forming a lower pattern according to other embodiments and correspond to cross-sections cut along line I-II in FIG. 1.

Referring to FIG. 6, a resist film 300 and a lower film 200 may be formed on a substrate 100. The substrate 100, the lower film 200 and the resist film 300 may be substantially the same as those explained in FIG. 2. An exposure process may be performed on the resist film 300. The exposure process may be substantially the same as explained in FIG. 3. For example, after completing the exposure process, the material of a first part 310 in the resist film 300 may have a different structure from the material of a second part 320.

After that, a development process may be performed on the resist film 300 to form a resist pattern 300P. The development process may be performed by the method explained referring to FIG. 4. However, a polar developing solution may be used in the development process. The polar developing solution may include an alkaline solution. In an embodiment, the polar developing solution may include an alkylammonium hydroxide and an alcohol. The alkylammonium hydroxide may include, for example, tetramethylammonium hydroxide (TMAH). The alcohol may include isopropyl alcohol (IPA).

By the polar developing solution, the first part 310 of the resist film 300 may be removed to form a resist pattern 300P′. However, since the second part 320 of the resist film 300 is nonpolar, the second part 320 may not be removed by the developing solution. The resist pattern 300P′ may correspond to the second part 320 of the resist film 300. The resist pattern 300P′ may be a positive tone pattern. The ranges of the width W′ and distance D′ of the resist pattern 300P′ may be substantially the same as the width W and distance D of the resist pattern 300P in FIG. 4. The resist pattern 300P′ may include multiple pattern parts, and the distance D′ between the pattern parts may be about 20 nm to about 300 nm.

Referring to FIG. 7, a lower film 200 may be etched to form a lower pattern 200P′. However, the lower pattern 200P′ may be formed at a position corresponding to the second part 320 of the resist pattern 300P′. The etching of the lower film 200 may be substantially the same as the method explained referring to FIG. 5. After that, the resist pattern 300′ may be removed.

As referred to in embodiments, after exposing to ultraviolet light about 360 nm to about 370 nm, the formation of a positive pattern or a negative pattern may be determined according to the polar or nonpolar characteristics of a developing solution. However, if short wavelength light, including extreme ultraviolet (UV) or electron beam is irradiated, crosslinking by a fluorinated chain may act as a main mechanism, and solubility change may not arise in a polar developing solution, and a negative pattern may be formed by a nonpolar developing solution.

Hereinafter, referring to the experimental examples of the inventive concept, the preparation of a resist composition and the formation of a resist pattern will be explained. In the explanation of the experimental examples, room temperature may mean about 25° C.

1. Preparation of Compounds

(1) Synthesis of First Monomer (RFMI6 Introducing a Perfluoroalkylated Chain)

To a round-bottom flask (100 cm³), triphenylphosphine (2.70 g, 10.3 mmol) and tetrahydrofuran (hereinafter, THF) (25 cm³) were added to prepare a solution. After stirring, the solution was cooled to about 0° C. To the solution cooled, diisopropyl azodicarboxylate (2.10 g, 10.3 mmol) was added dropwisely to prepare a reaction mixture. The reaction mixture was stirred for about 10 minutes. A solution of 5,5,6,6,7,7,8,8,9,9,10,10,10-tridecafluorodecan-1-ol (4.80 g, 12.4 mmol) dissolved in THF (10 cm³) was added to the reaction mixture. The reaction mixture was kept at about 0° C. for about 5 minutes using an ice bath, and maleimide (1.00 g, 10.3 mmol) was added to the reaction mixture. The ice bath was removed, and the reaction mixture was stirred at room temperature (about 25° C.) for about 12 hours to perform the reaction. The reaction may be performed by Reaction 2. After finishing the reaction, ethyl acetate was added to the reaction mixture, and extraction was performed. An extract including a product in ethyl acetate was washed with water and a saturated sodium chloride aqueous solution. Then, an organic solution in which the product was dissolved was separated. To the organic solution thus separated, anhydrous MgSO₄ was injected and stirred to remove moisture in the product. The product was filtered and concentrated. The product was purified through column chromatography (stationary phase: silica gel, mobile phase: ethyl acetate:hexane=1:4) to obtain a final product (RFMI6) of a white solid.

[Yield Analysis]

The mass of the final product (RFMI6) was 3.50 g. The yield was analyzed as 72%.

[Nuclear Magnetic Resonance (NMR) Analysis]

The chemical shift values (δ) of the material thus synthesized, measured by ¹H NMR (400 MHz, CDCl₃) were 6.71 (s, 2H), 3.56 (t, J=7 Hz, 2H), 2.19-2.00 (m, 2H), 1.75-1.58 (m, 4H).

Accordingly, the final product thus synthesized (RFMI6) was confirmed as 1-(5,5,6,6,7,7,8,8,9,9,10,10,10-tridecafluorodecyl)-1H-pyrrole-2,5-dione.

(2) Synthesis and Preparation of Second Monomer

### Synthesis of 4-Hydroxystyrene (HOST)

To a one-neck, round-bottom flask (250 cm³), methyltriphenylphosphonium bromide (13.2 g, 36.8 mmol) and tetrahydrofuran (48 cm³) were injected, and potassium tert-butoxide (6.9 g, 61.5 mmol) was added to prepare a mixture. The mixture was stirred at room temperature for about 10 minutes. After that, a solution of 4-hydroxybenzaldehyde (3 g, 24.6 mmol) dissolved in THF (24 cm³) was added to the mixture. The mixture was stirred at room temperature for about 1 hour. A saturated ammonium chloride aqueous solution was added to the mixture to finish the reaction. The reaction was finished, and a product was formed. Under vacuum distillation conditions, THE in the product was removed. The product was added to dichloromethane (DMC) and extracted. The extracted product was washed with water and a saturated sodium chloride aqueous solution. Accordingly, an organic solution in which the product was dissolved was separated. To the organic solution thus separated, anhydrous MgSO₄ was injected and stirred to remove moisture in the product. The product was filtered and concentrated. The product was purified through column chromatography (stationary phase: silica gel, mobile phase: ethyl acetate:hexane=1:9) to obtain a final product of a bright yellow solid.

[Yield Analysis]

The mass of the final product was 3.62 g. The yield was analyzed as 92%.

[Nuclear Magnetic Resonance (NMR) Analysis]

The chemical shift values (6) of the material thus synthesized, measured by ¹H NMR (400 MHz, CDCl₃) were 7.3 (d, J=8.5 Hz, 2H), 6.79 (d, J=8.6 Hz, 2H), 6.65 (d, J=17.6 Hz 2H), 5.60 (d, J=17.6 Hz, 1H), 5.12 (d, J=17.6 Hz, 1H), 4.94 (s, 1H).

Accordingly, the final product thus synthesized was confirmed as 4-hydroxystyrene.

### Synthesis of tert-butyl 2-(4-vinylphenoxy)acetate (tBAST)

To a one-neck, round-bottom flask (100 cm³), 4-hydroxystryene (1.53 g, 12.7 mmol), potassium carbonate (3.52 g, 25.50 mmol), sodium iodide (3.81 g, 25.47 mmol), 18-crown-6 (0.34 g, 1.27 mmol), and acetone (30 cm³) were added to prepare a mixture. The mixture was stirred at room temperature for about 5 minutes. To the mixture, tert-butyl bromoacetate (4.97 g, 25.47 mmol) was added dropwisely, and by using a refluxing cooler, the mixture was stirred at a temperature of about 80° C. for about 20 hours to perform the reaction. After finishing the reaction, a product was extracted using ethyl acetate. The product thus extracted was washed with water and a saturated sodium chloride aqueous solution. To the product thus obtained, anhydrous MgSO₄ was injected and stirred to remove moisture in the product. The product was filtered and concentrated. The product was purified through column chromatography (stationary phase: silica gel, mobile phase: ethyl acetate:hexane=1:9). A final product (tBAST) of a colorless liquid was obtained.

[Yield Analysis]

The mass of the final product was 2.05 g. The yield was analyzed as 90%.

[Nuclear Magnetic Resonance (NMR) Analysis]

The chemical shift values (6) of the material thus synthesized, measured by ¹H NMR (400 MHz, CDCl₃) were 7.34 (d, J=8 Hz, 2H), 6.85 (d, J=8.4 Hz, 2H), 6.64 (m, 1H), 5.61 (d, J=17.2 Hz, 2H), 5.14 (d, J=10.4 Hz, 2H), 4.51 (s, 2H), 1.49 (s, 9H).

Accordingly, the final product thus synthesized was confirmed as tert-butyl 2-(4-vinylphenoxy)acetate.

### [Synthesis of 4-[(tert-butoxycarbonyl)oxy]styrene(tBOCST)]

To a one-neck, round-bottom flask (50 cm³), 4-hydroxystyrene (1.24 g, 10.3 mmol) and 4-dimethylaminopyridine (0.63 g, 5.16 mmol) were added to prepare a mixture. To the mixture, anhydrous THE (12 cm³) was injected for dissolution. A solution of di-tert-butyl dicarbonate (9.01 g, 41.28 mmol) dissolved in anhydrous THE (6 cm³) was added to the mixture and reacted at room temperature for about 1 hour. After finishing the reaction, the product thus obtained was added to ethyl acetate for extraction. The product thus extracted was washed with water and a saturated sodium chloride aqueous solution. Then, an organic solution in which the product was dissolved was separated. To the organic solution thus separated, anhydrous MgSO₄ was injected and stirred to remove moisture in the product. The product was filtered and concentrated, and then, purified through column chromatography (stationary phase: silica gel, mobile phase: ethyl acetate:hexane=1:9). A final product (tBOCST) of a colorless liquid was obtained.

[Yield Analysis]

The mass of the final product was 2.05 g. The yield was analyzed as 90%.

[Nuclear Magnetic Resonance (NMR) Analysis]

The chemical shift values (6) of the material thus synthesized, measured by ¹H NMR (400 MHz, CDCl₃) were 7.4 (d, J=8.4 Hz, 2H), 7.12 (d, J=8.4 Hz, 2H), 6.69 (m, 1H), 5.69 (d, J=18.4 Hz, 2H), 5.25 (d, J=11.2 Hz, 2H), 1.56 (s, 9H).

Accordingly, the final product thus synthesized was confirmed as 4-[(tert-butoxycarbonyl)oxy]styrene.

### [Experimental Example 1A] Synthesis of P(R_{F}MI6-tBOS) Polymer

To a Schlenk tube (25 cm³), 1-(5,5,6,6,7,7,8,8,9,9,10,10,10-tridecafluorodecyl)-1H-pyrrole-2,5-dione (R_{F}MI6) (0.5 g, 1.06 mmol) synthesized above, 4-tert-butoxystyrene (purchased from SigmaAldrich) (0.187 g, 1.06 mmol), 4-cyano-4(dodecylsulfanylthiocarbonyl)sulfanyl pentanoic acid (CDSTSP) (0.01 g, 0.027 mmol) and 2,2′-azobis(2-methylpropionitrile) (AIBN) (0.002 g, 0.013 mmol) were added under a nitrogen atmosphere to prepare a solution. Benzotrifluoride (3 cm³) bubbled with a nitrogen gas was injected into the solution under nitrogen conditions. A series of freeze-pump-thaw processes was repeated three times to remove oxygen in the solution. The solution was stirred at a temperature of about 90° C. for about 12 hours. Then, the solution in the tube was added to hexane (50 cm³) dropwisely to form a precipitate. The precipitate was filtered and dried. 0.5 g of a final product of P(R_{F}MI6-tBOS) was obtained.

[Nuclear Magnetic Resonance (NMR) Analysis]

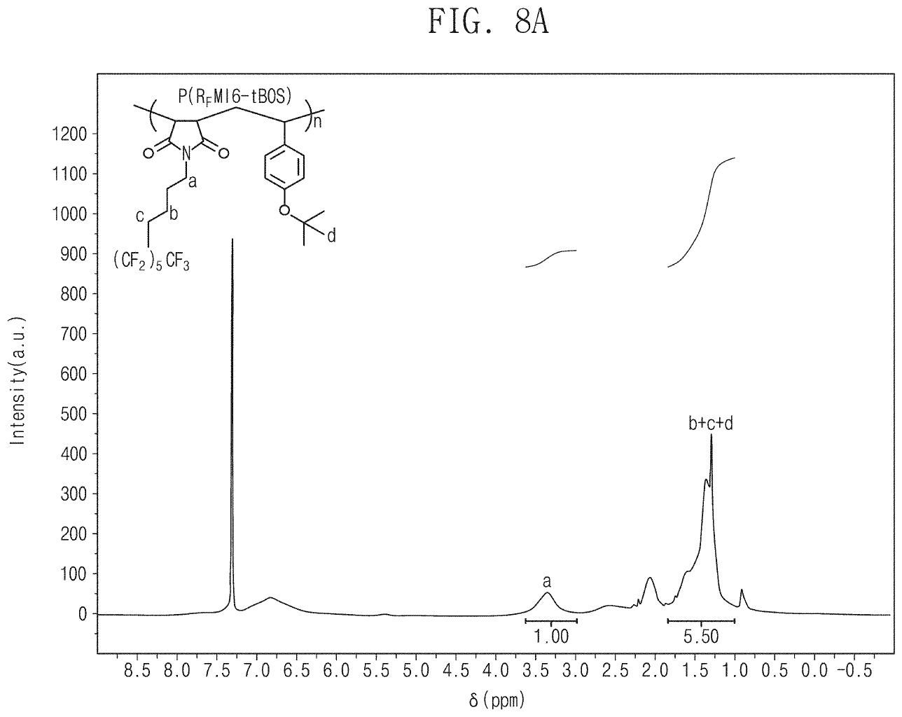

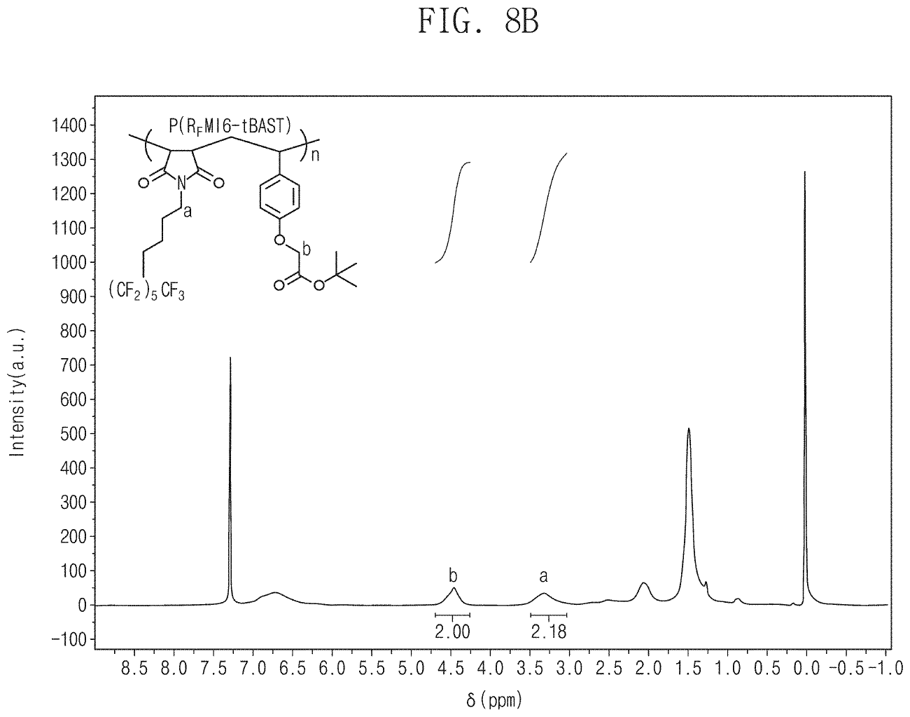

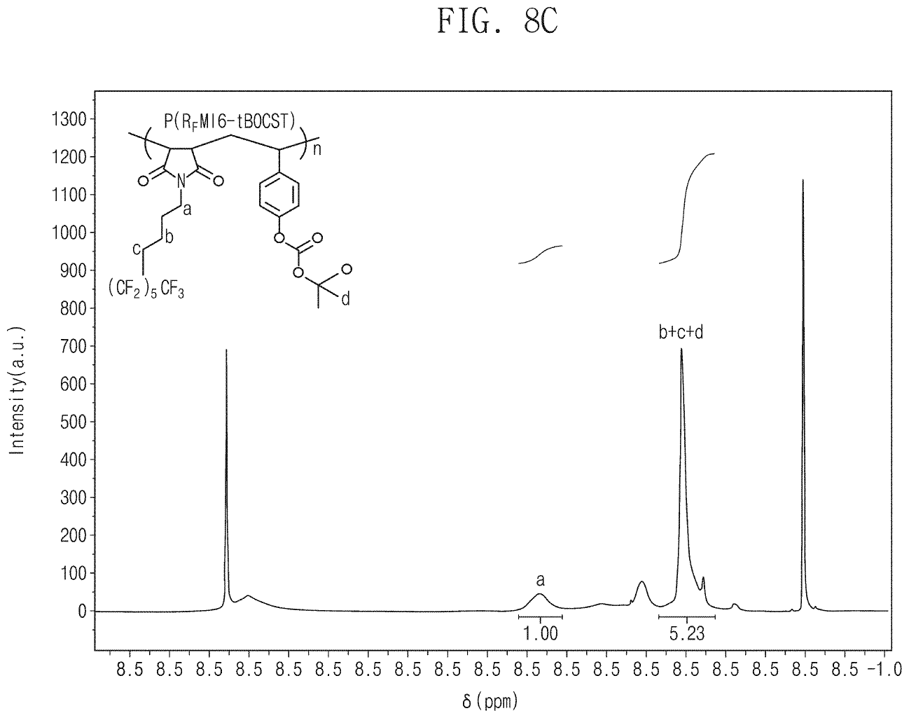

FIG. 8A shows nuclear magnetic resonance (¹H NMR) spectrum results of a product of Experimental Example 1A. The x-axis represents δ (ppm), and the y-axis represents an intensity (unit: arbitrary value, a.u.).

Referring to FIG. 8A, the final product thus synthesized was confirmed as a material represented by Formula 3A.

### [Experimental Example 1B] Synthesis of P(R_{F}MI6-tBAST) Polymer

To a Schlenk tube (25 cm³), 1-(5,5,6,6,7,7,8,8,9,9,10,10,10-tridecafluorodecyl)-1H-pyrrole-2,5-dione (R_{F}MI6) (0.5 g, 1.06 mmol), tert-butyl 2-(4-vinylphenoxy)acetate (0.25 g, 1.06 mmol), 4-cyano-4(dodecylsulfanylthiocarbonyl)sulfanyl pentanoic acid (CDSTSP) (0.01 g, 0.027 mmol) and 2,2′-azobis(2-methylpropionitrile) (AIBN) (0.002 g, 0.013 mmol) were added under a nitrogen atmosphere to prepare a solution. Benzotrifluoride (3 cm³) bubbled with a nitrogen gas was injected into the solution under nitrogen conditions. A series of a freeze process, a pump process, and a thaw process was repeated three times to remove oxygen in the solution. The solution was stirred at a temperature of about 90° C. for about 12 hours. Then, the solution in the tube was added to hexane (50 cm³) dropwisely to form a precipitate. The precipitate was filtered and dried. 0.65 g of a final product of P(R_{F}MI6-tBAST) was obtained.

[Nuclear Magnetic Resonance (NMR) Analysis]

FIG. 8B shows nuclear magnetic resonance (¹H NMR) spectrum results of a product of Experimental Example 1B. The x-axis represents δ (ppm), and the y-axis represents an intensity (unit: arbitrary value, a.u.).

Referring to FIG. 8B, the final product synthesized in Experimental Example 1B was confirmed as a material represented by Formula 3B.

### [Experimental Example 1C] Synthesis of P(R_{F}MI6-tBOCST) Polymer

To a Schlenk tube (25 cm³), 1-(5,5,6,6,7,7,8,8,9,9,10,10,10-tridecafluorodecyl)-1H-pyrrole-2,5-dione (R_{F}MI6) (0.5 g, 1.06 mmol) synthesized above, 4-(tert-butoxycarbonyloxy)styrene (tBOCST) (0.23 g, 1.06 mmol), 4-cyano-4(dodecylsulfanylthiocarbonyl)sulfanyl pentanoic acid (CDSTSP) (0.01 g, 0.027 mmol), and 2,2′-azobis(2-methylpropionitrile) (AIBN) (0.002 g, 0.013 mmol) were added under a nitrogen atmosphere to prepare a solution. Benzotrifluoride (3 cm³) bubbled with a nitrogen gas was injected into the solution under nitrogen conditions. A series of a freeze process, a pump process, and a thaw process was repeated three times to remove oxygen in the solution. The solution was stirred at a temperature of about 90° C. for about 12 hours. Then, the solution in the tube was added to hexane (50 cm³) dropwisely to form a precipitate. The precipitate was filtered and dried. 0.59 g of a final product of P(R_{F}MI6-tBOCST) was obtained.

[Nuclear Magnetic Resonance (NMR) Analysis]

FIG. 8C shows nuclear magnetic resonance (¹H NMR) spectrum results of a product of Experimental Example 1C. The x-axis represents δ (ppm), and the y-axis represents an intensity (unit: arbitrary value, a.u.).

Referring to FIG. 8C, the final product synthesized in Experimental Example 1C was confirmed as a material represented by Formula 3C.

### [Comparative Example 1] Preparation of Resist Compound of P(R_{F}MI6-St)

To a Schlenk tube (25 cm³), R_{F}MI6 (0.40 g, 0.85 mmol) synthesized above, styrene (0.09 g, 0.85 mmol), and 2,2′-azobis(2-methylpropionitrile) (AIBN) (0.01 g, 0.06 mmol) were added under a nitrogen atmosphere. Benzotrifluoride (6 cm³) bubbled with a nitrogen gas was injected into the mixture under nitrogen conditions. Then, the mixture was stirred at a temperature of about 80° C. for about 12 hours to perform the reaction shown in Reaction 5 below. Then, to the solution in the tube, hexane (50 cm³) was added dropwisely to form a precipitate. The precipitate was filtered and dried. A final product of P(R_{F}MI6-St) was obtained.

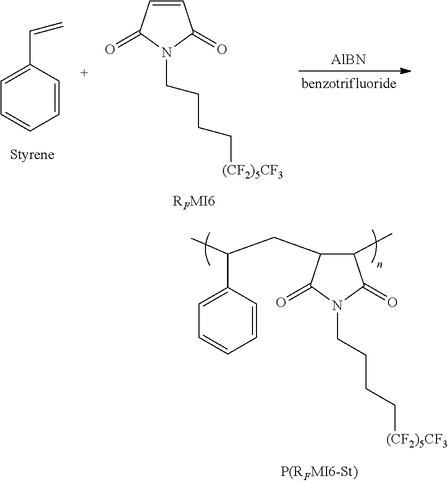

(In Reaction 5, “n” may be an integer between 10 and 150.)

### [Experimental Example 2A] Preparation of Resist Solution

In PF-7600 (purchased from 3M Co.), P(R_{F}MI6-tBOS) (10 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 5 wt % of the P(R_{F}MI6-tBOS).

### [Experimental Example 2B] Formation of Resist Film

The resist solution of Experimental Example 2A was applied on a silicon substrate at about 1000 rpm for about 60 seconds by spin coating. The coated solution was heated at about 110° C. for about 1 minute to form a resist thin film.

### [Experimental Example 2C] Preparation of a P(R_{F}MI6-tBAST) Solution and Formation of Thin Film

By the same method as Experimental Example 2A, a resist solution was prepared. However, the resist solution was prepared using P(R_{F}MI6-tBAST) instead of P(R_{F}MI6-tBOS).

### [Experimental Example 2D] Preparation of a P(R_{F}MI6-tBOCST) Solution and Formation of Thin Film

By the same method as Experimental Example 2A, a resist solution was prepared. However, the resist solution was prepared using P(R_{F}MI6-tBOCST) instead of P(R_{F}MI6-tBOS).

### [Experimental Example 3A] Evaluation 1 of Ultraviolet Lithography of P(R_{F}MI6-tBOS)

On the resist thin film of Experimental Example 2B, ultraviolet of about 365 nm (i-line) was irradiated under conditions of 120 mJ/cm², followed by heating at about 80° C. for about 1 minute. The resist thin film was developed using PF-7600 for about 60 seconds. As a result of the development process, the formation of a negative tone pattern was observed.

### [Experimental Example 3B] Evaluation 1 of Ultraviolet Lithography of P(R_{F}MI6-tBOS)

By the same method as Experimental Example 2A, a resist solution was prepared. However, the resist solution was prepared using P(R_{F}MI6-tBAST) instead of P(R_{F}MI6-tBOS). By using the resist solution, a resist thin film and a resist pattern were formed by the same method as Experimental Example 2B. After that, the evaluation of ultraviolet lithography was performed by the same method as in Experimental Example 3A, and the formation of a negative tone pattern was observed.

### [Experimental Example 3C] Evaluation 1 of Ultraviolet Lithography of P(R_{F}MI6-tBOCST)

By the same method as Experimental Example 2A, a resist solution was prepared. However, the resist solution was prepared using P(R_{F}MI6-tBOCST) instead of P(R_{F}MI6-tBOS). By using the resist solution, a resist thin film and a resist pattern were formed by the same method as Experimental Example 2B. After that, the evaluation of ultraviolet lithography was performed by the same method as in Experimental Example 3A, and the formation of a negative tone pattern was observed.

### [Experimental Example 4A] Evaluation 2 of Ultraviolet Lithography of P(R_{F}MI6-tBOS)

A resist thin film was formed by the same method as in Experimental Example 2B. However, the resist solution was applied after treating a silicon substrate with hexamethyldisilazane (HMDS).

On the resist thin film, ultraviolet of about 365 nm (i-line) was irradiated under conditions of 80 mJ/cm², followed by heating at about 90° C. for about 1 minute to perform a post-exposure bake (PEB) process. A developing solution was prepared by mixing a 0.26 M TMAH aqueous solution and isopropyl alcohol (IPA) in a volume ratio of 70%:30%. By using the developing solution, a development process was performed with respect to the exposed resist thin film for about 30 seconds. After the development process, a washing process was performed using DI water. As a result of the development process and washing process, the formation of a positive tone pattern was observed.

### [Experimental Example 4B] Evaluation 2 of Ultraviolet Lithography of P(R_{F}MI6-tBOS)

By the same method as Experimental Example 2A, a resist solution was prepared. However, the resist solution was prepared using P(R_{F}MI6-tBAST) instead of P(R_{F}MI6-tBOS). By using the resist solution, a resist thin film and a resist pattern were formed by the same method as Experimental Example 2B. After that, the evaluation of ultraviolet lithography was performed by the same method as in Experimental Example 4A, and the formation of a positive tone pattern was observed.

### [Experimental Example 4C] Evaluation 2 of Ultraviolet Lithography of P(R_{F}MI6-tBOCST)

By the same method as Experimental Example 2A, a resist solution was prepared. However, the resist solution was prepared using P(R_{F}MI6-tBOCST) instead of P(R_{F}MI6-tBOS). By using the resist solution, a resist thin film and a resist pattern were formed by the same method as Experimental Example 2B. After that, the evaluation of ultraviolet lithography was performed by the same method as in Experimental Example 4A, and the formation of a positive tone pattern was observed.

### [Comparative Example 2A] Evaluation of Lithography

In PF-7600 (purchased from 3M Co.), a material represented by Formula 6A below was dissolved to prepare a resist solution. A resist thin film was formed by the same method as in Experimental Example 3.

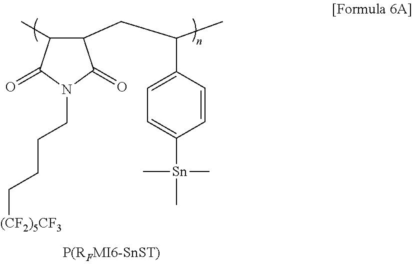

(In Formula 6A, “n” may be an integer between 10 and 150.)

### [Comparative Example 2B] Evaluation of Lithography

In PF-7600 (purchased from 3M Co.), a material represented by Formula 6B below was dissolved to prepare a resist solution. A resist thin film was formed by the same method as in Experimental Example 3.

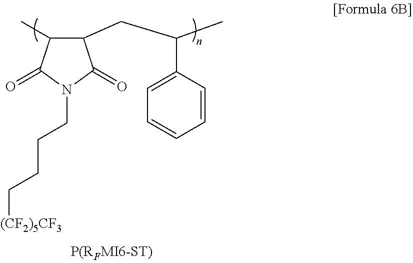

(In Formula 6B, “n” may be an integer between 10 and 150.)

### [Experimental Example 5A] Evaluation 1 of Solubility Properties of P(R_{F}MI6-tBOS)

In PF-7600, P(R_{F}MI6-tBOS) (3 wt/vol %) was dissolved to prepare a resist solution. The resist solution was applied on a silicon substrate at about 2000 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 50 to about 1,500 μC/cm² was irradiated onto the resist thin film. On the exposed resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 5B] Evaluation 2 of Solubility Properties of P(R_{F}MI6-tBOS)

In PF-7600, P(R_{F}MI6-tBOS) (3 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 10 wt % of the P(R_{F}MI6-tBOS).

The resist solution thus prepared was applied on a silicon substrate at about 2000 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 50 to about 1,500 μC/cm² was irradiated onto the resist thin film. The exposed resist thin film was heated at about 100° C. for about 1 minute to perform a post-exposure bake (PEB) process. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 6A] Evaluation 3 of Solubility Properties of P(R_{F}MI6-tBOS)

In PF-7600, P(R_{F}MI6-tBOS) (3 wt/vol %) was dissolved to prepare a resist solution. The resist solution was applied on a silicon substrate at about 2000 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 50 to about 1,500 μC/cm² was irradiated onto the resist thin film. On the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 6B] Evaluation 4 of Solubility Properties of P(R_{F}MI6-tBOS)

In PF-7600, P(R_{F}MI6-tBOS) (3 wt/vol %) and a photo acid generator of triphenylsulfonium nonaflate (TPS-Nf) were dissolved to prepare a resist solution. In this case, the triphenylsulfonium nonaflate (TPS-Nf) was about 10 wt % of the P(R_{F}MI6-tBOS).

The resist solution thus prepared was applied on a silicon substrate at about 2000 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 50 to about 1,500 μC/cm² was irradiated onto the resist thin film. The exposed resist thin film was heated at about 100° C. for about 1 minute to perform a post-exposure bake (PEB) process. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 7A] Evaluation 1 of Solubility Properties of P(R_{F}MI6-tBOS) with Respect to PF-7600

In PF-7600, P(R_{F}MI6-tBOS) (3 wt/vol %) was dissolved to prepare a resist solution. The resist solution was applied on a silicon substrate at about 2000 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 20 to about 600 μC/cm² was irradiated onto the resist thin film. On the resist thin film, a development process was performed using PF-7600 or n-butyl acetate (nBA) for about 30 seconds. A thickness was measured through Alpha-step® D-300 stylus profiler manufactured by Kla-Tencor Co. to evaluate solubility properties.

### [Experimental Example 7B] Evaluation 1 of Solubility Properties of P(R_{F}MI6-tBOS) with Respect to nBA

A resist solution was prepared, a thin film was formed, and an exposure process was performed by the same method as in Experimental Example 7A. However, the development process after the exposure process was performed using n-butyl acetate (nBA). The solubility properties of the resist thin film were evaluated.

### [Experimental Example 7C] Evaluation 2 of Solubility Properties of P(R_{F}MI6-tBOS) with Respect to PF-7600

In PF-7600, P(R_{F}MI6-tBOS) (3 wt/vol %) and a photo acid generator of triphenylsulfonium nonaflate (TPS-Nf) were dissolved to prepare a resist solution. In this case, the triphenylsulfonium nonaflate (TPS-Nf) was about 10 wt % of the P(R_{F}MI6-tBOS).

The resist solution thus prepared was applied on a silicon substrate at about 2250 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 20 to about 600 μC/cm² was irradiated onto the resist thin film. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 7D] Evaluation 2 of Solubility Properties of P(R_{F}MI6-tBOS) with Respect to nBA

A resist solution was prepared, a thin film was formed, and an exposure process was performed by the same method as in Experimental Example 7C. However, the development process after the exposure process was performed using n-butyl acetate (nBA). The solubility properties of the resist thin film were evaluated.

### [Experimental Example 7E] Evaluation 3 of Solubility Properties of P(R_{F}MI6-tBOS) with Respect to PF-7600

In PF-7600, P(R_{F}MI6-tBOS) (3 wt/vol %) and a photo acid generator of triphenylsulfonium nonaflate (TPS-Nf) were dissolved to prepare a resist solution. In this case, the triphenylsulfonium nonaflate (TPS-Nf) was about 10 wt % of the P(R_{F}MI6-tBOS).

The resist solution thus prepared was applied on a silicon substrate at about 2250 rpm for about 60 seconds by spin coating. The coated resist solution was heated at about 110° C. for about 1 minute to form a resist thin film with a thickness of about 100 nm.

Under an acceleration voltage of about 80 keV, an electron beam of about 20 to about 600 μC/cm² was irradiated onto the resist thin film. The exposed resist thin film was heated at about 110° C. for about 1 minute to perform a post-exposure bake (PEB) process. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 7F] Evaluation 3 of Solubility Properties of P(R_{F}MI6-tBOS) with Respect to nBA

A resist solution was prepared, a thin film was formed, and an exposure process and a post-exposure bake process were performed by the same method as in Experimental Example 7E. However, the development process after the exposure process was performed using n-butyl acetate (nBA). The solubility properties of the resist thin film were evaluated.

### [Experimental Example 8A] Evaluation 5 of Solubility Properties of P(R_{F}MI6-tBOS)

In PF-7600, P(R_{F}MI6-tBOS) (3 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 5 wt % of the P(R_{F}MI6-tBOS).

A resist thin film was formed using the resist solution by the same method as in Experimental Example 2B. However, the resist thin film was formed into a thickness of about 100 nm.

Under an acceleration voltage of about 80 keV, an electron beam of about 50 to about 1,500 μC/cm² was irradiated onto the resist thin film. The exposed resist thin film was heated at about 80° C. for about 1 minute to perform a post-exposure bake (PEB) process. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 8B] Evaluation 1 of Solubility Properties of P(R_{F}MI6-tBAST)

A resist solution was prepared by the same method as in Experimental Example 8A. However, the resist solution was prepared by using P(R_{F}MI6-tBAST) instead of P(R_{F}MI6-tBOS). By using the resist solution, a resist thin film was formed by the same method as in Experimental Example 6A, and the solubility properties of the resist thin film were evaluated.

### [Experimental Example 8C] Evaluation 1 of Solubility Properties of P(R_{F}MI6-tBOCST)

A resist solution was prepared by the same method as in Experimental Example 8A. However, the resist solution was prepared by using P(R_{F}MI6-tBOCST) instead of P(R_{F}MI6-tBOS). By using the resist solution, a resist thin film was formed by the same method as in Experimental Example 6A, and the solubility properties of the resist thin film were evaluated.

### [Experimental Example 9A] Evaluation 6 of Solubility Properties of P(R_{F}MI6-tBOS)

In PF-7600, P(R_{F}MI6-tBOS) (3 wt/vol %) and a photo acid generator of triphenylsulfonium nonaflate (TPS-Nf) were dissolved to prepare a resist solution. In this case, the triphenylsulfonium nonaflate (TPS-Nf) was about 5 wt % of the P(R_{F}MI6-tBOS).

A resist thin film was formed using the resist solution by the same method as in Experimental Example 2B. However, the resist thin film was formed into a thickness of about 100 nm.

Under an acceleration voltage of about 80 keV, an electron beam of about 50 to about 1,500 μC/cm² was irradiated onto the resist thin film. The exposed resist thin film was heated at about 80° C. for about 1 minute to perform a post-exposure bake (PEB) process. Then, on the resist thin film, a development process was performed using PF-7600 for about 30 seconds. A thickness was measured through Alpha-step® D-300 stylus profiler manufactured by Kla-Tencor Co. to evaluate solubility properties.

### [Experimental Example 9B] Evaluation 2 of Solubility Properties of P(R_{F}MI6-tBAST)

A resist solution was prepared by the same method as in Experimental Example 9A. However, the resist solution was prepared by using P(R_{F}MI6-tBAST) instead of P(R_{F}MI6-tBOS). By using the resist solution, a resist thin film was formed by the same method as in Experimental Example 6A, and the solubility properties of the resist thin film were evaluated.

### [Experimental Example 9C] Evaluation 2 of Solubility Properties of P(R_{F}MI6-tBOCST)

A resist solution was prepared by the same method as in Experimental Example 9A. However, the resist solution was prepared by using P(R_{F}MI6-tBOCST) instead of P(R_{F}MI6-tBOS). By using the resist solution, a resist thin film was formed by the same method as in Experimental Example 6A, and the solubility properties of the resist thin film were evaluated.

### [Experimental Example 10A] Evaluation of Electron Beam Lithography Performance of P(R_{F}MI6-tBOS)

In PF-7600, P(R_{F}MI6-tBOS) (3 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 5 wt % of the P(R_{F}MI6-tBOS).

The resist solution was applied on a silicon substrate at about 1250 rpm for about 60 seconds by spin coating. The coated solution was heated at about 110° C. for about 1 minute to form a resist thin film.

Under an acceleration voltage of about 80 keV, an electron beam of about 50 to about 1,500 μC/cm² was irradiated onto the resist thin film. The exposed resist thin film was heated at about 80° C. for about 1 minute to perform a post-exposure bake (PEB) process. Then, on the resist thin film, a development process was performed using PF-7600 for about 30 seconds to form a resist pattern. As a result of the development process, a negative tone resist pattern with a size of about tens of nanometers was formed.

### [Experimental Example 10B] Evaluation of Electron Beam Lithography Performance of P(R_{F}MI6-tBAST)

A resist solution was prepared by the same method as in Experimental Example 2A. However, the resist solution was prepared by using P(R_{F}MI6-tBAST) instead of P(R_{F}MI6-tBOS). By using the resist solution, a resist thin film and a resist pattern were formed by the same method as in Experimental Example 7A. The resist pattern was a negative tone pattern with a size of tens of nanometers.

### [Experimental Example 10C] Evaluation of Electron Beam Lithography Performance of P(R_{F}MI6-tBOCST)

A resist solution was prepared by the same method as in Experimental Example 2A. However, the resist solution was prepared by using P(R_{F}MI6-tBOCST) instead of P(R_{F}MI6-tBOS). By using the resist solution, a resist thin film was formed by the same method as in Experimental Example 7A. As a result of a development process, a negative tone pattern with a size of tens of nanometers was formed.

### [Experimental Example 11A] Evaluation 1 of Patterning Performance of P(R_{F}MI6-tBOS) Under Electron Beam Lithography Conditions

In PF-7600, P(R_{F}MI6-tBOS) (1.3 wt/vol %) was dissolved to prepare a resist solution. The resist solution was applied on a silicon substrate at about 1250 rpm for about 60 seconds by spin coating. The coated solution was heated at about 110° C. for about 1 minute to form a resist thin film with a thickness of about 50 nm.

Under an acceleration voltage of about 80 keV, an electron beam of about 50 to about 1,500 μC/cm² was irradiated onto the resist thin film. On the resist thin film, a development process was performed using PF-7600 for about 30 seconds. As a result of the development process, a negative tone resist pattern with a size of about tens of nanometers was formed.

### [Experimental Example 11B] Evaluation 2 of Patterning Performance of P(R_{F}MI6-tBOS) Under Electron Beam Lithography

In PF-7600, P(R_{F}MI6-tBOS) (1.3 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 10 wt % of the P(R_{F}MI6-tBOS).

The resist solution was applied on a silicon substrate at about 1250 rpm for about 60 seconds by spin coating. The coated solution was heated at about 110° C. for about 1 minute to form a resist thin film with a thickness of about 50 nm.

Under an acceleration voltage of about 80 keV, an electron beam of about 50 to about 1,500 μC/cm² was irradiated onto the resist thin film. The exposed resist thin film was heated at about 100° C. for about 1 minute to perform a post-exposure bake (PEB) process. Then, on the resist thin film, a development process was performed using PF-7600 for about 30 seconds. As a result of the development process, a negative tone resist pattern with a size of about tens of nanometers was formed.

### [Experimental Example 12A] Evaluation 1 of Solubility Properties of P(R_{F}MI6-tBOS) Under Extreme Ultraviolet Conditions

In PF-7600, P(R_{F}MI6-tBOS) (3 wt/vol %) was dissolved to prepare a resist solution.

The resist solution was applied on a silicon substrate at about 2000 rpm for about 60 seconds by spin coating. The coated solution was heated at about 110° C. for about 1 minute to form a thin film with a thickness of about 100 nm.

Under an acceleration voltage of about 80 keV, extreme ultraviolet was irradiated onto the resist thin film under conditions of about 5 to about 30 mJ/cm². Then, on the resist thin film, a development process was performed using PF-7600 for about 30 seconds to form a resist pattern. By measuring the thickness of the resist pattern according to the exposure dose, the change of solubility properties were observed.

### [Experimental Example 12B] Evaluation 2 of Solubility Properties of P(R_{F}MI6-tBOS) Under Extreme Ultraviolet Conditions

In PF-7600, P(R_{F}MI6-tBOS) (3 wt/vol %) and a photo acid generator of nonafluorobutanesulfonyloxy-1,8-naphthalimide were dissolved to prepare a resist solution. In this case, the nonafluorobutanesulfonyloxy-1,8-naphthalimide was about 10 wt % of the P(R_{F}MI6-tBOS).

The resist solution was applied on a silicon substrate at about 2000 rpm for about 60 seconds by spin coating. The coated solution was heated at about 110° C. for about 1 minute to form a thin film with a thickness of about 100 nm.

Under an acceleration voltage of about 80 keV, extreme ultraviolet was irradiated onto the resist thin film under conditions of about 5 to about 30 mJ/cm². Then, on the resist thin film, a development process was performed using PF-7600 for about 30 seconds. By measuring the thickness of a resist pattern according to the exposure dose, the change of solubility properties were observed.

### [Experimental Example 13A] Evaluation 3 of Solubility Properties of P(R_{F}MI6-tBOS) Under Extreme Ultraviolet Conditions

In PF-7600, P(R_{F}MI6-tBOS) (3 wt/vol %) was dissolved to prepare a resist solution.

The resist solution was applied on a silicon substrate at about 2000 rpm for about 60 seconds by spin coating. The coated solution was heated at about 110° C. for about 1 minute to form a thin film with a thickness of about 100 nm.

Under an acceleration voltage of about 80 keV, extreme ultraviolet was irradiated onto the resist thin film under conditions of about 5 to about 30 mJ/cm². Then, on the resist thin film, a development process was performed using PF-7600 for about 30 seconds to form a resist pattern. By measuring the thickness of the resist pattern according to the exposure dose, the change of solubility properties were observed.

### [Experimental Example 13B] Evaluation 4 of Solubility Properties of P(R_{F}MI6-tBOS) Under Extreme Ultraviolet Conditions

In PF-7600, P(R_{F}MI6-tBOS) (3 wt/vol %) and a photo acid generator of triphenylsulfonium nonaflate were dissolved to prepare a resist solution. In this case, the triphenylsulfonium nonaflate was about 5 wt % of the P(R_{F}MI6-tBOS).

The resist solution was applied on a silicon substrate at about 200 rpm for about 60 seconds by spin coating. The coated solution was heated at about 110° C. for about 1 minute to form a thin film with a thickness of about 100 nm.

Under an acceleration voltage of about 80 keV, extreme ultraviolet was irradiated onto the resist thin film under conditions of about 5 to about 30 mJ/cm². Then, on the resist thin film, a development process was performed using PF-7600 for about 30 seconds. By measuring the thickness of a resist pattern according to the exposure dose, the change of solubility properties were observed.

Table 1 shows measured results of the number average molecular weight (Mn), polydispersity index (PDI), and glass transition temperature of Experimental Example 1A, Experimental Example 1B, Experimental Example 1C, and Comparative Example 1. The number average molecular weight and the polydispersity index were analyzed by gel permeation chromatography (hereinafter, GPC) and nuclear magnetic resonance spectrum (¹H NMR). The glass transition temperature was measured through difference scanning calorimetry (hereinafter, DSC) analysis.

TABLE 1

| | Comparative | Experimental | Experimental | Experimental |
|---|---|---|---|---|
| | Example 1 | Example 1A | Example 1B | Example 1C |
| Resist | P(R_{F}MI6- | P(R_{F}MI6- | P(R_{F}MI6- | P(R_{F}MI6- |
| compound | ST) | tBOS) | tBAST) | tBOCST) |
| Number | 12,200 | 12,300 | 15,900 | 8,900 |
| average | | | | |
| molecular | | | | |
| weight | | | | |
| (Mn)(g/mol) | | | | |
| Polydispersity | 1.4 | 1.33 | 1.43 | 1.34 |
| index (PDI) | | | | |
| Glass transition | 97° C. | 138° C. | 121° C. | 116° C. |
| temperature | | | | |
| (° C.) | | | | |

Referring to Table 1, Experimental Example 1A, Experimental Example 1B, and Experimental Example 1C showed higher glass transition temperatures than that of Comparative Example 1.

It could be confirmed that Experimental Example 1A, Experimental Example 1B, and Experimental Example 1C showed relatively low polydispersity indexes. Particularly, the polydispersity indexes of Experimental Example 1A, Experimental Example 1B, and Experimental Example 1C were analyzed as about 1.0 to about 1.5.

Table 2 shows evaluation results of solubility properties of Experimental Example 1A, Experimental Example 1B, and Experimental Example 1C. The solubility properties were evaluated for coating solvents. In Table 2, O means soluble, and X means insoluble.

TABLE 2

| | | Experimental | Experimental | Experimental |
|---|---|---|---|---|
| | | Example 1A | Example 1B | Example 1C |
| | | P(R_{F}MI6- | P(R_{F}MI6- | P(R_{F}MI6- |
| Resist compound | | tBOS) | tBAST) | tBOCST) |
| Fluorine | HFE-7700 | X | X | X |
| solvent | PF-7600 | O | O | O |
| | HFE-7500 | X | X | X |
| | HFE-7300 | X | X | X |
| | HFE-7200 | X | X | X |
| | HFE-7100 | X | X | X |
| | FC-40 | X | X | X |
| | FC-43 | X | X | X |
| | FC-770 | X | X | X |
| | FC-3283 | X | X | X |
| Organic | PGMEA | X | X | X |
| solvent | PGME | X | X | X |
| | Cyclohexanone | O | O | O |

Referring to Table 2, the compounds formed in Experimental Example 1A, Experimental Example 1B, and Experimental Example 1C showed solubility with respect to cyclohexanone and PF-7600 before exposure. However, through Experimental Examples 2A, 2C and 2D, it could be confirmed that PF-7600 showed capacity of forming a uniform thin film for three compounds.

Table 3A shows evaluation results of solubility properties for the developing solutions of the resist patterns of Experimental Example 3A, Experimental Example 3B, Experimental Example 3C under the I-line exposure. Table 3B shows evaluation results of solubility properties for the developing solutions of the resist patterns of Experimental Example 4A, Experimental Example 4B, and Experimental Example 4C under the I-line exposure. In Table 3A and Table 3B, O means that solubility change was shown before and after the exposure, X means that solubility change was not shown before and after the exposure, and A means that solubility change was shown before and after the exposure, but a residual film was partially present. In Table 3A and Table 3B3, a mixture solution of TMAH and IPA was prepared by mixing 0.26 M tetramethyl ammonium hydroxide (TMAH) and isopropanol (IPA) in a volume ratio of 7:3.

TABLE 3A

| | | Experimental | Experimental Experimental | |
|---|---|---|---|---|
| | | Example 3A | Example 3B | Example 3C |
| | | P(R_{F}MI6- | P(R_{F}MI6- | P(R_{F}MI6- |
| Resist compound | | tBOS) | tBAST) | tBOCST) |
| Fluorine | HFE-7700 | X | X | X |
| solvent | PF-7600 | O | O | O |
| | HFE-7500 | X | X | X |
| | HFE-7300 | X | X | X |
| | HFE-7200 | X | X | X |
| | HFE-7100 | X | X | X |
| | FC-40 | X | X | X |
| | FC-43 | X | X | X |
| | FC-770 | X | X | X |
| | FC-3283 | X | X | X |

TABLE 3B

| | | Experimental | Experimental | Experimental |
|---|---|---|---|---|
| | | Example 4A | Example 4B | Example 4C |
| | | P(R_{F}MI6- | P(R_{F}MI6- | P(R_{F}MI6- |
| Resist compound | | tBOS) | tBAST) | tBOCST) |
| Organic | PGMEA | Δ | Δ | O |
| solvent | PGME | X | X | X |
| | Cyclohexanone | Δ | Δ | Δ |
| | n-butyl acetate | X | X | X |
| | 0.26M TMAH | X | X | X |
| | Mixture solution of | O | O | O |
| | TMAH and IPA | | | |

Referring to Table 3A, the resist patterns of Experimental Example 3A, Experimental Example 3B, and Experimental Example 3C showed excellent solubility with respect to PF-7600. If the resist films of Experimental Example 3A, Experimental Example 3B, and Experimental Example 3C are developed using PF-7600, negative resist patterns with a uniform line width may be formed.

Referring to Table 3B, the resist patterns of Experimental Example 4A, Experimental Example 4B, and Experimental Example 4C showed excellent solubility with respect to the mixture solution of TMAH and IPA. If the resist films of Experimental Example 4A, Experimental Example 4B, and Experimental Example 4C are developed using the mixture solution of TMAH and IPA, positive resist patterns with a uniform line width may be formed.

Table 4 showed evaluation results of solubility properties with respect to the developing solutions of the resist patterns of Experimental Example 3A, and Experimental Example 4A. The resist pattern of Experimental Example 4A was formed using a mixture solution of TMAH and IPA in a volume ratio of 5:2 as a developing solution.

TABLE 4

| | Experimental | Experimental |
|---|---|---|
| | Example 3A | Example 4A |
| Resist compound | P(R_{F}MI6-tBOS) | P(R_{F}MI6-tBOS) |
| Dose during exposure | 120 mJ/cm² | 80 mJ/cm² |
| process | | |
| Developing solution | PF-7600 | Mixture solution of |
| | | TMAH and IPA |
| Resist pattern tone | Negative tone pattern | Positive tone pattern |

Referring to Table 4, the resist pattern of Experimental Example 3A was prepared using a nonpolar developing solution of PF-7600. As a result of a development process, the resist pattern was formed as a negative tone pattern.

The resist pattern of Experimental Example 4A was prepared using a mixture solution of TMAH and IPA, which is a polar developing solution. As a result of a development process, the resist pattern was formed as a positive tone pattern.

Table 5 shows evaluation results of solubility properties on the developing solutions of resist patterns of Experimental Example 8A, Experimental Example 8, and Experimental Example 8C under the exposure of extreme ultraviolet and electron beam. In Table 5, O means that solubility change was shown before and after the exposure, X means that solubility change was not shown before and after the exposure, and A means that solubility change was shown before and after the exposure, but a residual film was partially present. In Table 5, a mixture solution of TMAH and TPA was prepared by mixing 0.26 M tetramethyl ammonium hydroxide (TMAH) and isopropanol (IPA) in a volume ratio of 7:3.

TABLE 5

| | | Experimental | Experimental | Experimental |
|---|---|---|---|---|
| | | Example 8A | Example 8B | Example 8C |
| | | P(R_{F}MI6- | P(R_{F}MI6- | P(R_{F}MI6- |
| Resist compound | | tBOS) | tBAST) | tBOCST) |
| Fluorine | HFE-7700 | X | X | X |
| solvent | PF-7600 | O | O | O |
| | HFE-7500 | X | X | X |
| | HFE-7300 | X | X | X |
| | HFE-7200 | X | X | X |
| | HFE-7100 | X | X | X |
| | FC-40 | X | X | X |
| | FC-43 | X | X | X |
| | FC-770 | X | X | X |
| | FC-3283 | X | X | X |
| Organic | PGMEA | X | X | X |
| solvent | PGME | X | X | X |
| | Cyclohexanone | X | X | X |
| | n-butyl acetate | O | O | O |
| | 0.26M TMAH | X | X | X |
| | Mixture solution of | Δ | Δ | Δ |
| | TMAH and IPA | | | |

Referring to Table 5, the resist patterns of Experimental Example 8A, Experimental Example 8B, and Experimental Example 8C showed definite solubility change with respect to PF-7600 and n-butyl acetate (nBA) before and after the exposure. If the resist films of Experimental Example 7A, Experimental Example 7B, Experimental Example 7C, Experimental Example 7D, Experimental Example 7E, and Experimental Example 7F are developed using PF-7600 and n-butyl acetate, negative resist patterns may be formed.

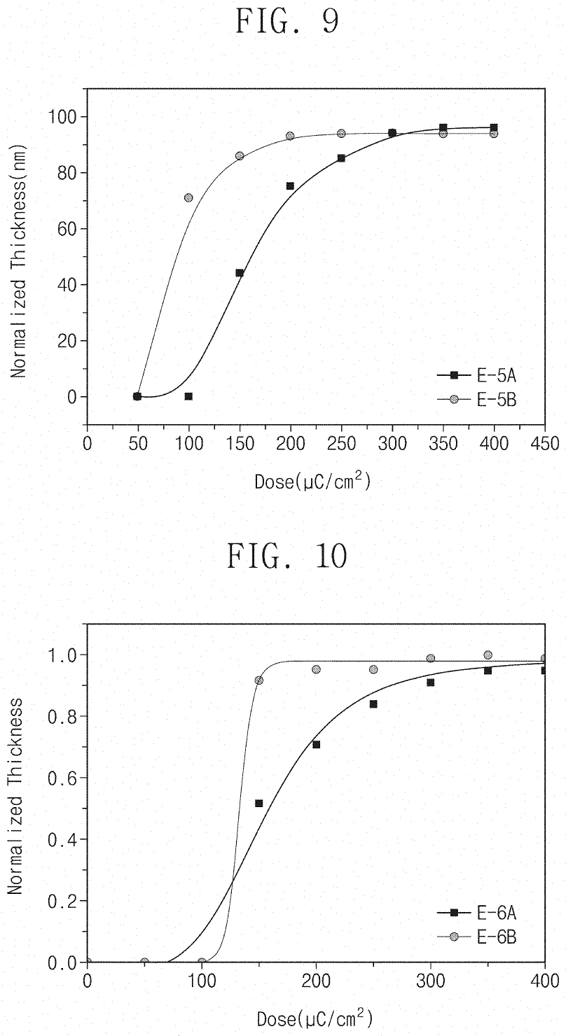

FIG. 9 is a graph for evaluating solubility properties of resist thin films of Experimental Example 5A and Experimental Example 5B, in cases of including a nonionic photo acid generator. The horizontal axis represents a dose, and the vertical axis represents a normalized thickness. The material represented by Formula 5 was used as a nonionic photo acid generator.

Referring to FIG. 9, the resist thin film with a thickness of about 100 nm of Experimental Example 5A (E-5A) showed a sensitivity of about 300 μC/cm². The resist thin film with a thickness of about 100 nm of Experimental Example 5B (E-5B) showed a sensitivity of about 200 μC/cm². The resist composition of Experimental Example 5B (E-5B) included a photo acid generator, and the resist thin film may show improved sensitivity.

FIG. 10 is a graph for evaluating solubility properties of resist thin films of Experimental Example 6A and Experimental Example 6B, in cases of including an ionic photo acid generator. The horizontal axis represents a dose, and the vertical axis represents a normalized thickness. The material represented by Formula 6 was used as an ionic photo acid generator.

Referring to FIG. 10, the resist thin film with a thickness of about 100 nm of Experimental Example 6A (E-6A) showed a sensitivity of about 300 μC/cm². The resist thin film with a thickness of about 100 nm of Experimental Example 6B (E-6B) showed a sensitivity of about 160 μC/cm². The resist composition of Experimental Example 6B (E-6B) included an ionic photo acid generator, and the resist thin film may show improved sensitivity when compared to a case of including a nonionic photo acid generator.

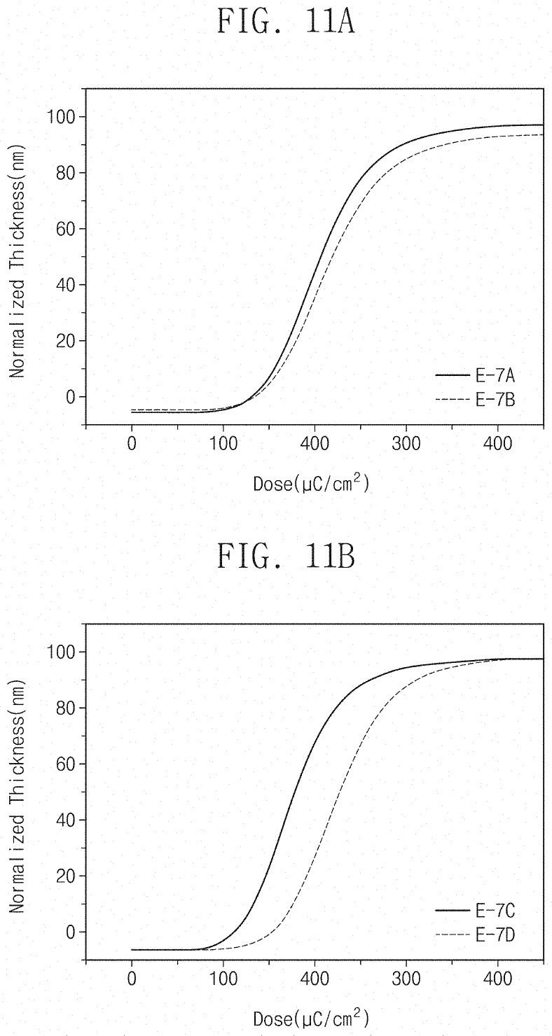

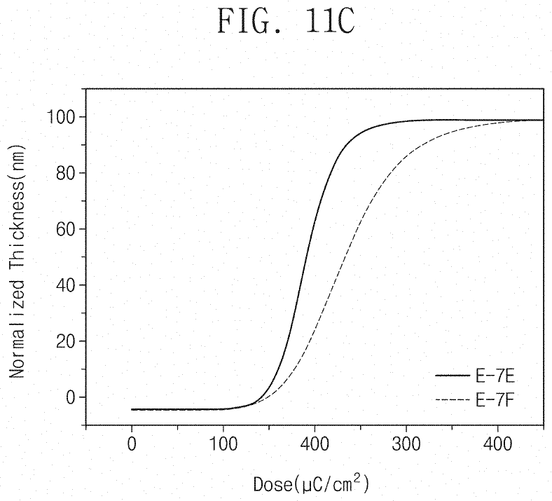

FIG. 11 are graphs for evaluating solubility properties of resist thin films of Experimental Example 7A, Experimental Example 7B, Experimental Example 7C, Experimental Example 7D, Experimental Example 7E, and Experimental Example 7F with respect to a developing agent of PF-7600 and nBA. The horizontal axis represents a dose, and the vertical axis represents a normalized thickness.

Referring to FIG. 11, the resist thin film with a thickness of about 100 nm of Experimental Example 7A (E-7A) showed a sensitivity of about 325 μC/cm², if developed with PF-7600, and a case of Experimental Example 7B (E-7B) using nBA as a developing agent showed a sensitivity of about 360 μC/cm². The resist thin film with a thickness of about 100 nm of Experimental Example 7C (E-7C) showed a sensitivity of about 295 μC/cm², if developed with PF-7600, and a case of Experimental Example 7D (E-7D) using nBA as a developing agent showed a sensitivity of about 370 μC/cm². The resist thin film with a thickness of about 100 nm of Experimental Example 7E (E-7E) showed a sensitivity of about 260 μC/cm², if developed with PF-7600, and a case of Experimental Example 7F (E-7F) using nBA as a developing agent showed a sensitivity of about 370 μC/cm². The resist compositions of Experimental Example 7A (E-7A), Experimental Example 7C (E-7C) and Experimental Example 7E (E-7E) may show improved sensitivity, if PF-7600 is applied as a developing agent.

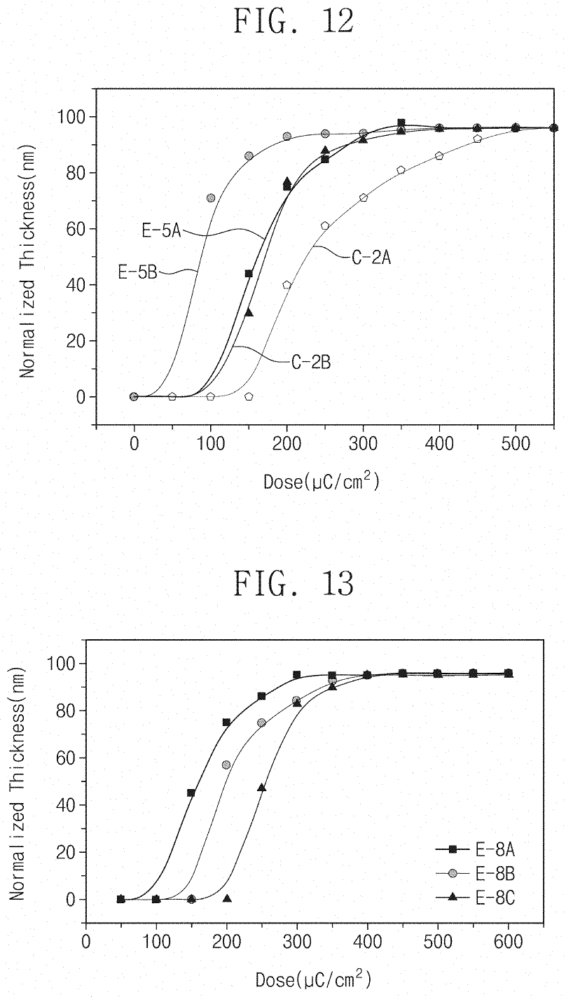

FIG. 12 is a graph for evaluating the solubility properties of resist thin films of Experimental Example 5A, Experimental Example 5B, Comparative Example 2A, and Comparative Example 2B. The horizontal axis represents a dose, and the vertical axis represents a normalized thickness.

Referring to FIG. 12, the resist thin film with a thickness of about 100 nm of Experimental Example 5B (E-5B) showed a sensitivity of about 200 μC/cm². The resist thin film with a thickness of about 100 nm of Comparative Example 2B (P(R_{F}M16-ST) (C-2B) showed a sensitivity of about 300 μC/cm². The resist thin film with a thickness of about 100 nm of Experimental Example 5A (E-5A) showed a sensitivity of about 300 μC/cm². The resist thin film with a thickness of about 100 nm of Comparative Example 2A (P(R_{F}M16-SnST) (C-2A) showed a sensitivity of about 500 μC/cm². The resist thin film of Experimental Example 5B (E-5B) showed improved sensitivity than the resist thin film of Comparative Example 2A (C-2A) and the resist thin film of Comparative Example 2B (C-2B).

FIG. 13 is a graph for evaluating solubility properties of resist thin films of Experimental Example 8A, Experimental Example 8B, and Experimental Example 8C, in cases of including a nonionic photo acid generator. The horizontal axis represents a dose, and the vertical axis represents a normalized thickness. The material represented by Formula 5 was used as a nonionic photo acid generator.

Referring to FIG. 13, the resist thin film with a thickness of about 100 nm of Experimental Example 8A (E-8A) showed a sensitivity of about 300 μC/cm². The resist thin film with a thickness of about 100 nm of Experimental Example 8B (E-8B) showed a sensitivity of about 350 μC/cm². The resist thin film with a thickness of about 100 nm of Experimental Example 8C (E-8C) showed a sensitivity of about 400 μC/cm². The resist compositions of Experimental Example 8A (E-8A), Experimental Example 8B (E-8B) and Experimental Example 8C (E-8C) may show improved sensitivity.

FIG. 14 is a graph for evaluating solubility properties of resist thin films of Experimental Example 9A, Experimental Example 9B, and Experimental Example 9C, in cases of including an ionic photo acid generator. The horizontal axis represents a dose, and the vertical axis represents a normalized thickness. The material represented by Formula 6 was used as a nonionic photo acid generator.

Referring to FIG. 14, the resist thin film with a thickness of about 100 nm of Experimental Example 9A (E-9A) showed a sensitivity of about 160 μC/cm². The resist thin film with a thickness of about 100 nm of Experimental Example 9B (E-9B) showed a sensitivity of about 275 μC/cm². The resist thin film with a thickness of about 100 nm of Experimental Example 9C (E-9C) showed a sensitivity of about 350 μC/cm². The resist compositions of Experimental Example 9A (E-9A), Experimental Example 9B (E-9B) and Experimental Example 9C (E-9C) may show improved sensitivity.

Table 6 shows evaluated results on patterning properties of Experimental Example 10A, Experimental Example 10B, and Experimental Example 10C. A critical dimension (CD) may correspond to the width W of a resist pattern 300P of FIG. 4 and the width W′ of a resist pattern 300P′ of FIG. 6. A pitch may mean a repeating period of the parts of a resist pattern. The sensitivity was evaluated by dose.

TABLE 6

| | Experimental | | Experimental | | Experimental | |
|---|---|---|---|---|---|---|
| | Example 10A | | Example 10B | | Example 10C | |
| | P(R_{F}MI6- | | P(R_{F}MI6- | | P(R_{F}MI6- | |
| Resist compound | tBOS) | | tBAST) | | tBOCST) | |
| Critical Dimension | 70 | nm | 70 | nm | 70 | nm |
| (CD) | | | | | | |
| Pitch | 200 | nm | 200 | nm | 200 | nm |
| Sensitivity | 1100 | μC/cm² | 1350 | μC/cm² | 1350 | μC/cm² |

Referring to FIG. 6, the resist patterns of Experimental Example 10A, Experimental Example 10B, and Experimental Example 10C may have minute widths. In the case where the electron beam dose was about 1100 μC/cm², the resist pattern of Experimental Example 10A showed a critical dimension of about 70 nm. In the case where the electron beam dose was about 1350 μC/cm², the resist patterns of Experimental Example 10B and Experimental Example 10C showed a critical dimension of about 70 nm.

According to embodiments, the resist compositions include the copolymer represented by Formula 3A, and the resist films may have high sensitivity in a lithography process using electron beam.

Table 7 shows evaluated results of patterning properties of Experimental Example 11A and Experimental Example 11B. A critical dimension (CD) may correspond to the width W of a resist pattern 300P of FIG. 4 and the width W′ of a resist pattern 300P′ of FIG. 6. A pitch may mean a repeating period of the parts of a resist pattern. The sensitivity was evaluated by dose.

TABLE 7

| | Experimental | | Experimental | |
|---|---|---|---|---|
| | Example 11A | | Example 11B | |
| Resist compound | P(R_{F}MI6-tBOS) | | P(R_{F}MI6-tBOS) | |
| Photo acid generator | Not included | | Included | |
| Thickness | 50 | nm | 50 | nm |
| Critical Dimension | 50 | nm | 50 | nm |
| Pitch | 130 | nm | 130 | nm |
| Sensitivity | 1300 | μC/cm² | 850 | μC/cm² |
| Line-edge roughness (LER) | 6.97 | nm | 7.02 | nm |
| Line width roughness (LWR) | 5.10 | nm | 5.47 | nm |

Referring to Table 7, in the case where the electron beam dose was about 1300 μC/cm², the resist pattern of Experimental Example 11A showed a critical dimension of about 50 nm. In the case where the electron beam dose was about 850 μC/cm², the resist pattern of Experimental Example 11B showed a critical dimension of about 50 nm. The resist pattern of Experimental Example 11A and the resist pattern of Experimental Example 11B showed excellent line-edge roughness properties and line width roughness properties.

According to embodiments, the resist compositions further included a photo acid generator, and the resist films showed high sensitivity in a lithography process using electron beam. Though the resist pattern further includes a photo acid generator, the resist pattern may show excellent resolution. The resolution of the resist pattern may be evaluated by the line-edge roughness properties and the line width roughness properties.

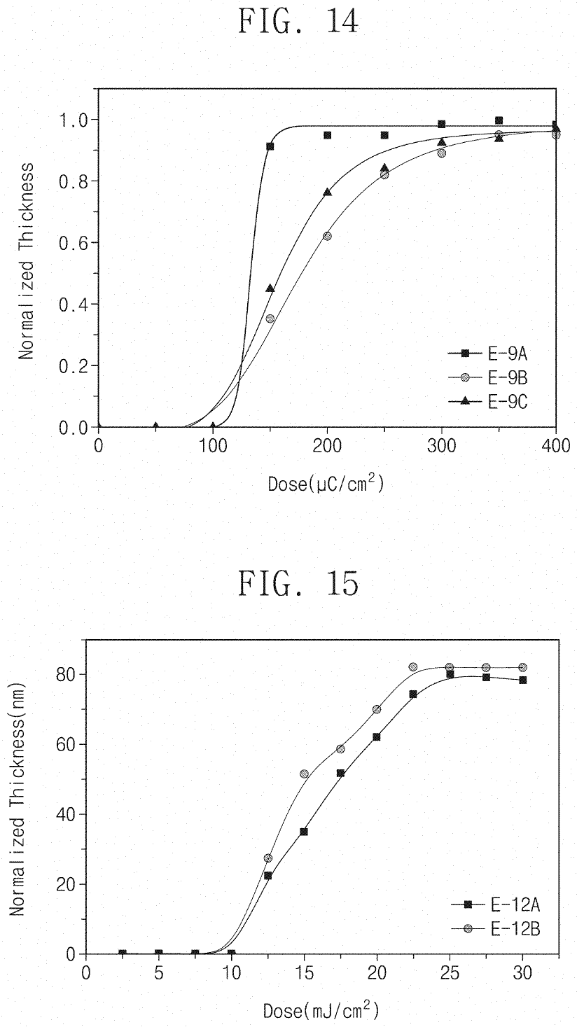

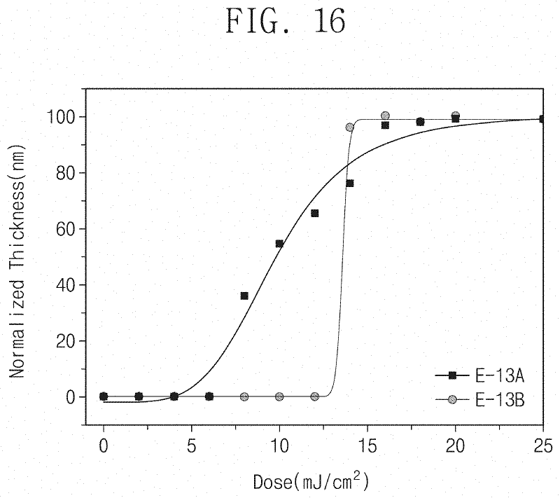

FIG. 15 is a graph for evaluating solubility properties of resist patterns on extreme ultraviolet of Experimental Example 12A and Experimental Example 12B. The horizontal axis represents a dose, and the vertical axis represents a normalized thickness.

Referring to FIG. 15, a sensitivity of about 25 mJ/cm² could be calculated from the solubility properties of Experimental Example 12A (E-12A). A sensitivity of about 20 mJ/cm² could be calculated from the solubility properties of Experimental Example 12B (E-12B).

FIG. 16 is a graph for evaluating solubility properties of resist patterns on extreme ultraviolet of Experimental Example 13A and Experimental Example 13B. The horizontal axis represents a dose, and the vertical axis represents a normalized thickness.

Referring to FIG. 16, a sensitivity of about 24 mJ/cm² could be calculated from the solubility properties of Experimental Example 13A (E-13A). A sensitivity of about 14 mJ/cm² could be calculated from the solubility properties of Experimental Example 13B (E-13B).

According to embodiments, the resist compositions further included a photo acid generator, and the resist films showed improved sensitivity in a lithography process using extreme ultraviolet.

According to the inventive concept, the composition includes an alternating copolymer and may show a uniform composition and narrow molecular weight distribution. The alternating copolymer may be prepared using a maleimide monomer having a highly halogenated alkyl group. By using the composition, a resist film may be formed. The resist film may have high sensitivity to light. The alternating copolymer may be prepared using a styrene monomer having an acid-cleavable protective group. Accordingly, the solubility of the resist film in a developing solution may be improved. The resolution of the resist pattern may be improved.

Although the embodiments of the present invention have been described, it is understood that the present invention should not be limited to the embodiments, but various changes and modifications can be made by one ordinary skilled in the art within the spirit and scope of the present invention as hereinafter claimed.

What is claimed is:

1. A composition comprising a copolymer represented by the following Formula 1: 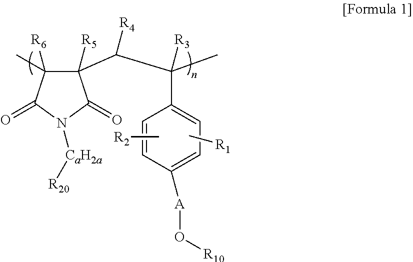
in Formula 1, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, R₁₀ is an alkyl group of 1 to 16 carbon atoms, R₂₀ is perhalogenated alkyl of 2 to 16 carbon atoms, perhalogenated alkyl ether perhalogenated alkyl of 2 to 16 carbon atoms, or halogenated-arene of 2 to 16 carbon atoms, “a” is any one integer selected from 1 to 11, and “n” is any one integer selected from 10 to 150.

2. The composition of claim 1, further comprising a photo acid generator.

3. The composition of claim 1, wherein, in Formula 1, R₂₀ is perfluoroalkyl of 2 to 11 carbon atoms or perfluoroalkyl ether perfluoroalkyl of 2 to 11 carbon atoms.

4. The composition of claim 1, wherein a material represented by Formula 1 comprises a material represented by the following Formula 2: 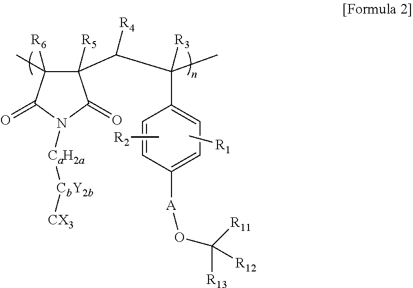
in Formula 2, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, each X is independently any one selected among F, Cl, Br and I, “a” is any one integer selected from 1 to 11, “b” is any one integer selected from 1 to 15, R₁₁, R₁₂ and R₁₃ are each independently an alkyl group of 1 to 5 carbon atoms, and “n” is any one integer selected from 10 to 150.

5. The composition of claim 4, wherein, in Formula 2, X and Y are F.

6. The composition of claim 1, wherein A in Formula 1 is represented by the following Formula A: 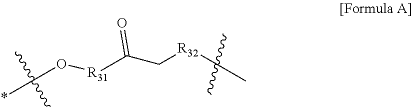
in Formula A, R₃₁ and R₃₂ are each independently any one selected from a single bond or a divalent alkyl group of 1 to 3 carbon atoms, and * is a part bonded to a benzene ring.

7. The composition of claim 1, wherein
the copolymer has a glass transition temperature of about 110° C. to about 150° C., and
the copolymer has a polydispersity index of about 1 to about 1.5.

8. The composition of claim 1, wherein a material represented by Formula 1 comprises a material represented by the following Formula 3A: 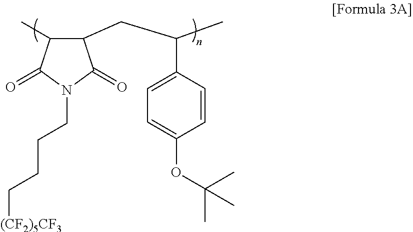
in Formula 3A, “n” is an integer between 10 and 150.

9. The composition of claim 1, wherein a material represented by Formula 1 comprises a material represented by the following Formula 3B: 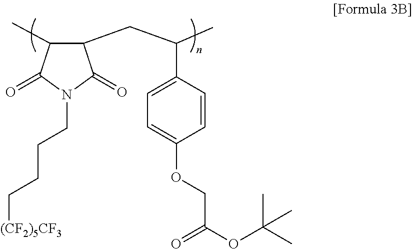
in Formula 3B, “n” is any one integer selected from 10 to 150.

10. The composition of claim 1, wherein a material represented by Formula 1 comprises a material represented by the following Formula 3C: 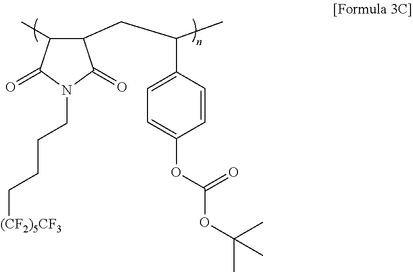
in Formula 3C, “n” is any one integer selected from 10 to 150.

11. A method of forming a pattern, the method comprising:
applying a compound represented by the following Formula 1 on a substrate to form a resist film; and
patterning the resist film: 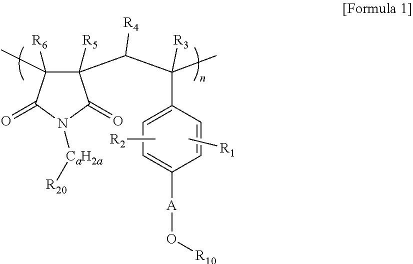
in Formula 1, R₁, R₂, R₃, R₄, R₅ and R₆ are each independently any one selected among hydrogen, deuterium and alkyl of 1 to 3 carbon atoms, A is a single bond, an alkyl group of 1 to 5 carbon atoms, an alkyl ether group of 1 to 8 carbon atoms, an ether alkyl group of 1 to 8 carbon atoms, an alkyl ester group of 1 to 8 carbon atoms, carbonate, or an acetal group of 1 to 8 carbon atoms, R₁₀ is an alkyl group of 1 to 16 carbon atoms, R₂₀ is perhalogenated alkyl of 2 to 16 carbon atoms, perhalogenated alkyl ether perhalogenated alkyl of 2 to 16 carbon atoms, or halogenated-arene of 2 to 16 carbon atoms, “a” is any one integer selected from 1 to 11, and “n” is any one integer selected from 10 to 150.

12. The method of forming a pattern of claim 11, wherein the patterning of the resist film comprises:
exposing the resist film to light to form an exposed part and an unexposed part; and
performing a development process using a developing solution on the resist film.

13. The method of forming a pattern of claim 12, wherein the developing solution comprises a polar developing solution, and the performing of the development process comprises removing the exposed part of the resist film.

14. The method of forming a pattern of claim 12, wherein the developing solution comprises a nonpolar developing solution, and the performing of the development process comprises removing the unexposed part of the resist film.
